(19) United States
(12) Patent Application Publication
(10) Pub. No.: US 2023/0217824 A1
(43) Pub. Date: Jul. 6, 2023

(54) LIGHT EMITTING DEVICE AND LIGHT EMITTING DISPLAY DEVICE INCLUDING THE SAME

(71) Applicant: LG Display Co., Ltd., Seoul (KR)

(72) Inventors: Chun Ki KIM, Paju-si (KR); Yu Jeong LEE, Paju-si (KR); Jung Keun KIM, Paju-si (KR)

(21) Appl. No.: 18/148,271

(22) Filed: Dec. 29, 2022

(30) Foreign Application Priority Data
Dec. 31, 2021 (KR) 10-2021-0194799

(51) Int. Cl. H10K 85/60; C09K 11/06; H10K 85/30

(52) U.S. Cl. CPC H10K 85/6572; C09K 11/06; H10K 85/654; H10K 85/624; H10K 85/6574; H10K 85/322; H10K 50/11

(57) ABSTRACT

Disclosed are a light emitting device that includes an additional layer adjacent to a light emitting layer and thus is capable of utilizing, in light emission, holes not used in the light emitting layer, to improve efficiency and lifespan, and a light emitting display device including the same. The light emitting device includes a first electrode and a second electrode facing each other, and an unit comprising a hole transport layer, a light emitting layer, an efficiency-improving layer, and an electron transport layer sequentially stacked between the first electrode and the second electrode, wherein the light emitting layer includes a first host comprising an anthracene derivative and a first blue light emitting dopant, and the efficiency-improving layer includes a second host having bipolarity and a second blue light emitting dopant.

### CROSS-REFERENCE TO RELATED APPLICATION(S)

This application claims the benefit of Korean Patent Application No. 10-2021-0194799, filed on Dec. 31, 2021, which is hereby incorporated by reference as if fully set forth herein.

### BACKGROUND

### Technical Field

The present disclosure relates to a light emitting device, and more particularly to a light emitting device that includes an efficiency-improving layer adjacent to a light emitting layer and thus is capable of utilizing, in light emission, holes that were consumed without being used for light excitation in the light emitting layer to improve efficiency and a light emitting display device including the same.

### Description of the Related Art

Recently, a light emitting display device that does not require a separate light source, realizes a compact configuration and displays clear color has been considered a competitive application.

Meanwhile, light emitting display devices include a plurality of subpixels and a light emitting device in each subpixel without a separate light source, thereby emitting light.

### BRIEF SUMMARY

Accordingly, the present disclosure is directed to a light emitting device and a light emitting display device including the same that substantially obviate one or more problems due to the limitations and disadvantages of the related art.

Light emitting devices have different luminous efficacies for respective colors and research has been conducted on blue light emitting devices. A blue fluorescent device improves efficiency using a triplet-triplet fusion (TTF) method and this method may cause a trade-off between efficiency and lifespan.

The light emitting device of the present disclosure has been devised to solve this problem. It is an object of the present disclosure to provide a light emitting device that is capable of improving both efficiency and lifespan using holes, which have not been used in a light emitting layer, for light emission through a separate layer adjacent to the light emitting layer, and a light emitting display device using the same.

Additional advantages, objects, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a light emitting device includes a first electrode and a second electrode facing each other, and a hole transport layer, a light emitting layer, an efficiency-improving layer, and an electron transport layer sequentially stacked between the first electrode and the second electrode, wherein the light emitting layer includes a first host comprising an anthracene derivative and a first blue light emitting dopant, and the efficiency-improving layer includes a second host having bipolarity and a second blue light emitting dopant.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a cross-sectional view illustrating a light emitting device according to an embodiment of the present disclosure;

FIG. 2 illustrates an energy band diagram of a light emitting layer and a peripheral layer;

FIG. 3 illustrates the movement of holes and electrons, main light emission and auxiliary light emission in the light emitting layer and the peripheral layer;

FIG. 4 is a cross-sectional view illustrating a light emitting device according to another embodiment of the present disclosure; and

FIG. 5 is a cross-sectional view illustrating a light emitting display device according to an embodiment.

### DETAILED DESCRIPTION

Reference will now be made in detail to preferred embodiments of the present disclosure, examples of which are illustrated in the accompanying drawings. Wherever possible, the same reference numbers will be used throughout the drawings to refer to the same or like parts. In the following description of the present disclosure, detailed descriptions of known functions and configurations incorporated herein will be omitted when the same may obscure the subject matter of the present disclosure. In addition, the names of elements used in the following description are selected in consideration of clarity of description of the specification, and may differ from the names of elements of actual products.

The shape, size, ratio, angle, number, and the like shown in the drawings to illustrate various embodiments of the present disclosure are merely provided for illustration, and the disclosure is not limited to the content shown in the drawings. Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure. When terms such as “including”, “having”, and “comprising” are used throughout the specification, an additional component may be present, unless “only” is used. A component described in a singular form encompasses a plurality thereof unless particularly stated otherwise.

The components included in the embodiments of the present disclosure should be interpreted to include an error range, even if there is no additional particular description thereof.

In describing the variety of embodiments of the present disclosure, when terms describing positional relationships such as “on”, “above”, “under” and “next to” are used, at least one intervening element may be present between the two elements, unless “immediately” or “directly” is used.

In describing the variety of embodiments of the present disclosure, when terms related to temporal relationships, such as “after”, “subsequently”, “next” and “before”, are used, the non-continuous case may be included, unless “immediately” or “directly” is used.

In describing the variety of embodiments of the present disclosure, terms such as “first” and “second” may be used to describe a variety of components, but these terms only aim to distinguish the same or similar components from one another. Accordingly, throughout the specification, a “first” component may be the same as a “second” component within the technical concept of the present disclosure, unless specifically mentioned otherwise.

Features of various embodiments of the present disclosure may be partially or completely coupled to or combined with each other, and may be variously inter-operated with each other and driven technically. The embodiments of the present disclosure may be carried out independently from each other, or may be carried out together in an interrelated manner.

In the following description of the present disclosure, the Lowest Unoccupied Molecular Orbital (LUMO) level and the Highest occupied Molecular Orbital (HOMO) level of a layer mean the LUMO level and the HOMO level of a material (i.e., a host) constituting a major weight ratio of the corresponding layer, unless they refer to the LUMO level and the HOMO level of a dopant material doping the corresponding layer.

As used herein, the term “HOMO energy level” is obtained by measuring the energy for electrons to be emitted from the surface upon UV irradiation. HOMO energy level can be measured by measuring the emitted photoelectrons with an electrometer and extrapolating the threshold value of photoelectron emission from the irradiation photon energy curve of the obtained photoelectron emission.

In addition, the HOMO and LUMO levels compared herein are based on the vacuum level and both are negative values. Therefore, when comparing two values, if one is lower than the other, it means that one is lower than the other based on the vacuum level and has a larger absolute value.

Then, the energy bandgap (Eg) is obtained by measuring the UV absorption spectrum, drawing a tangent line to the rising edge of the long wavelength of the absorption spectrum, and converting the wavelength, which intersects with the horizontal axis, into an energy value (E=hv/λ=h*C/λ, wherein h represents the Planck constant, C represents the speed of light, and λ, represents the wavelength of light).

As used herein, the term “doped” means that, in a material that accounts for most of the weight ratio of a layer, a material (for example, N-type and P-type materials, or organic and inorganic substances) having physical properties different from the material that occupies most of the weight ratio of the layer is added in an amount less than 30% by weight. In other words, the “doped” layer refers to a layer that is used to distinguish a host material from a dopant material of a certain layer, in consideration of the specific gravity of the weight ratio. Also, the term “undoped” refers to any case other than the “doped” case. For example, when a layer contains a single material or a mixture of materials having the same properties as each other, the layer is included in the “undoped” layer. For example, if at least one of the materials constituting a certain layer is P-type and not all materials constituting the layer are N-type, the layer is included in the “undoped” layer. For example, if at least one of materials constituting a layer is an organic material and not all materials constituting the layer are inorganic materials, the layer is included in the “undoped” layer. For example, when all materials constituting a certain layer are organic materials, at least one of the materials constituting the layer is N-type and the other is P-type, when the N-type material is present in an amount of less than 30 wt %, or when the P-type material is present in an amount of less than 30 wt %, the layer is included in the “doped” layer.

In the following description of the aspects, an electroluminescence (EL) spectrum is calculated by multiplying (1) a photoluminescence (PL) spectrum, in which unique characteristics of a luminescent material, such as a dopant material or a host material included in an organic light emitting layer, are reflected, by (2) an out-coupling emittance spectrum curve, determined according to the structure and optical characteristics of an organic light emitting device including thicknesses of organic layers, such as an electron transport layer, etc.

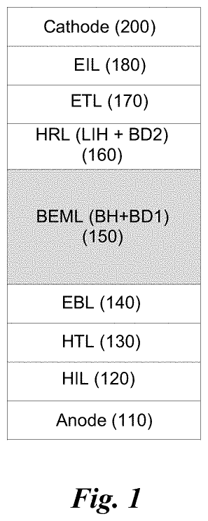

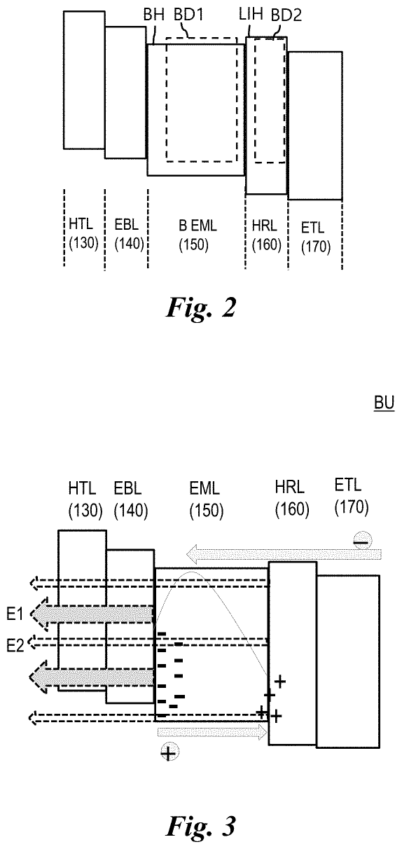

FIG. 1 is a cross-sectional view illustrating a light emitting device according to an embodiment of the present disclosure, FIG. 2 illustrates an energy band diagram of a light emitting layer and a peripheral layer, and FIG. 3 illustrates the movement of holes and electrons, main light emission and auxiliary light emission in the light emitting layer and the peripheral layer.

As shown in FIG. 1, the light emitting device of the present disclosure has a first electrode 110 and a second electrode 200 facing each other, and a hole injection layer 120 (HIL), a hole transport layer 130 (HTL), an electron-blocking layer 140 (EBL), a light emitting layer 150 (B EML), an efficiency-improving layer 160 (HRL), an electron transport layer 170 (ETL), and an electron injection layer 180 (EIL) stacked sequentially between the first electrode 110 and the second electrode 200.

The hole injection layer 120 is a layer that facilitates injection of holes from the first electrode 110, and may include a hole-transporting material and a P-type dopant, or an inorganic compound having a small work function difference with the first electrode 110.

In addition, the hole transport layer 130 functions to transfer holes from the hole injection layer 120 to the light emitting layer 150.

Similar to the hole transport layer 130, the electron-blocking layer 140 functions to transport holes and to prevent electrons from passing from the light emitting layer 150 to the hole transport layer 130. For this function, as shown in FIG. 2, the LUMO level of the electron-blocking layer 140 may be higher than the LUMO level of the host of the light emitting layer 150.

The light emitting layer 150 is a layer that has an emission peak at a wavelength of 400 nm to 490 nm and emits light of a blue wavelength in a visible light band. The light emitting layer 150 includes a host BH and a first blue light emitting dopant BD1. In addition, the first blue light emitting dopant BD1 exhibits light emission characteristics at a wavelength of 400 nm to 490 nm. For this purpose, a boron-based dopant, a pyrene-based dopant, or the like may be used.

The light emitting layer 150 emits fluorescence from the first blue light emitting dopant BD1 and induces fusion of triplets, which are not used for fluorescence, in order to increase the luminous efficacy of the light emitting layer 150. Luminous efficacy is increased by triplet-triplet fusion (TTF), in addition to fluorescence emission. For this purpose, the host (BH) may be an anthracene derivative that effectively causes triplet-triplet fusion.

As shown in FIG. 3, fast transmission is possible using the TTF mechanism in the light emitting layer 150, so the transmission is concentrated close to the electron-blocking layer 140 and thus main light emission E1 is intensively generated close to the interface between the light emitting layer 150 and the electron-blocking layer 140. For this purpose, the luminous efficacy is high, but there is a disadvantage in that the electron-blocking layer is deteriorated, so the lifespan decreases. In general, the lifespan is improved by improving the hole properties of the hole transport layer to reduce the deterioration of the electron-blocking layer. However, this causes a disadvantage of reduced efficacy.

The efficiency-improving layer 160 is called so because it functions to improve efficiency, and produces holes, which cannot be used for recombination with electrons in the light emitting layer 150, and are pushed to the opposite side of the electron-blocking layer 140, in the form of excitons again which are used for auxiliary light emission E2. Also, the efficiency-improving layer 160 can improve the lifespan by reducing the deterioration of the electron transport layer 170 due to hole accumulation. The bipolar portion of the second host LIH of the efficiency-improving layer 160 receives the holes confined in the light emitting layer 150, and the holes combine with electrons transferred from the electron transport layer 170 at one side of the efficiency-improving layer 160, thereby forming excitons. The energy of singlet excitons is transferred to the blue light emitting dopant BD2 to generate the auxiliary light emission E2.

For this purpose, as shown in FIG. 2, the efficiency-improving layer 160 may include a bipolar second host LIH having a large energy bandgap and a second blue light emitting dopant BD to realize blue light emission. Here, the second host (LIH) is a single material that is formed by chemical bonding between N-type and P-type materials and thus has both electron-transfer ability and hole-transfer ability, rather than requiring different independent N-type and P-type materials.

For this purpose, the second host LIH of the efficiency-improving layer 160 may be formed of a single compound including both an electron-transporting functional group and a hole-transporting functional group.

The compound as the second host (LIH) may include any one of a triazine- and a pyrimidine-based group, and at least one of a carbazole-, a spirofluorene-, and a dibenzofuran-based group.

In addition, the second host LIH is capable of emitting light and has an oscillator intensity f of 0.01 or more.

Here, the oscillator intensity (f) can be obtained through experimentation as follows.

fₑₓₚ=4.3×10⁻⁹∫εdv

wherein 6 and v represent a molar extinction coefficient (obtained from the absorption spectrum) and a wavenumber, respectively.

The difference (ΔEst) between the singlet excitation level and the triplet excitation level of the second host (LIH) may be not less than 0.01 eV and not more than 0.3 eV and the triplet excitation level of the second host may be not less than 2.7 eV and not more than 3.4 eV.

Also, the energy band gap of the second host LIH may be not less than 2.7 eV.

The second host LIH having the bipolarity described above may include the following material.

For example, when the compound as the second host (LIH) includes carbazole and pyrimidine, the compound may be selected from the following compounds LIH1 to LIH18:

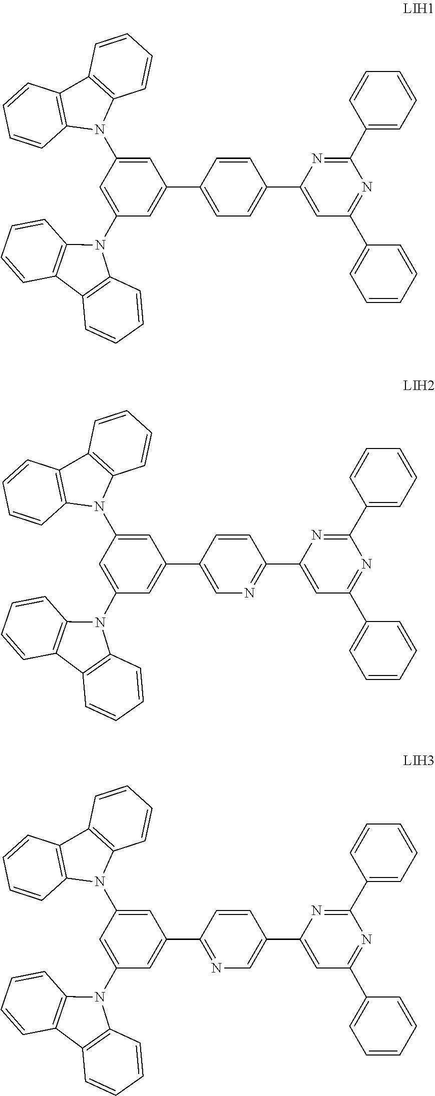 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)nc3)nc(-c3ccccc3)n2)cc1]

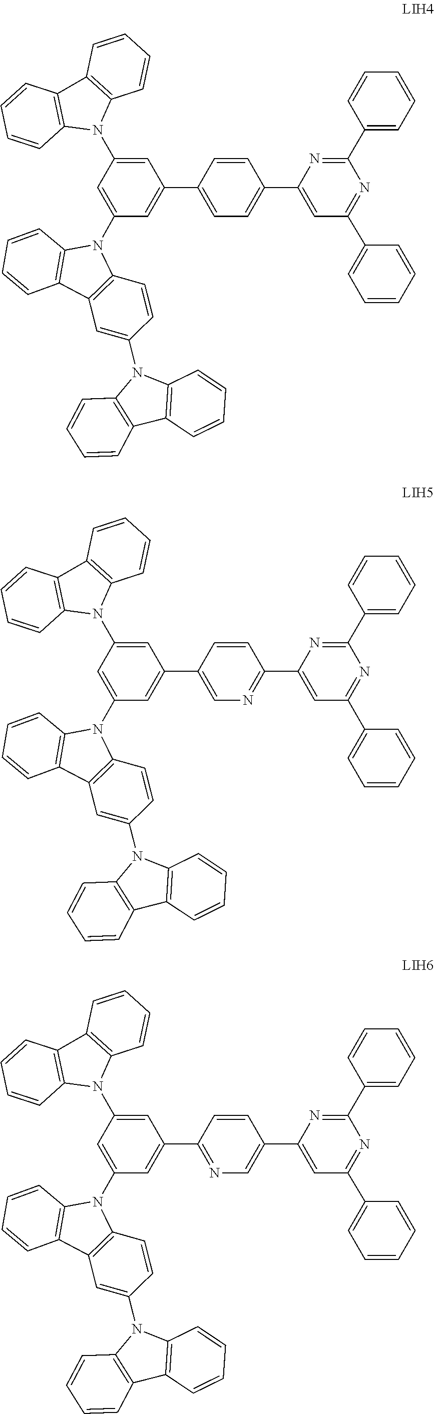 [SMILES: c1ccc(-c2cc(-c3ccc(-c4cc(-n5c6ccccc6c6ccccc65)cc(-n5c6ccccc6c6cc(-n7c8ccccc8c8ccccc87)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(-n7c8ccccc8c8ccccc87)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(-n7c8ccccc8c8ccccc87)ccc65)c4)nc3)nc(-c3ccccc3)n2)cc1]

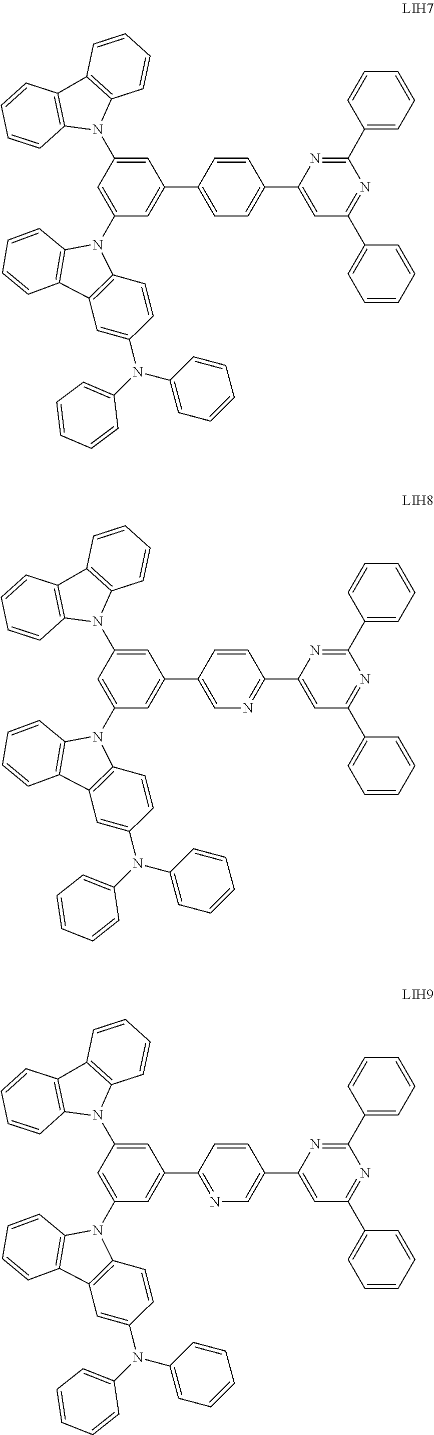 [SMILES: c1ccc(-c2cc(-c3ccc(-c4cc(-n5c6ccccc6c6ccccc65)cc(-n5c6ccccc6c6cc(N(c7ccccc7)c7ccccc7)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(N(c7ccccc7)c7ccccc7)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(N(c7ccccc7)c7ccccc7)ccc65)c4)nc3)nc(-c3ccccc3)n2)cc1]

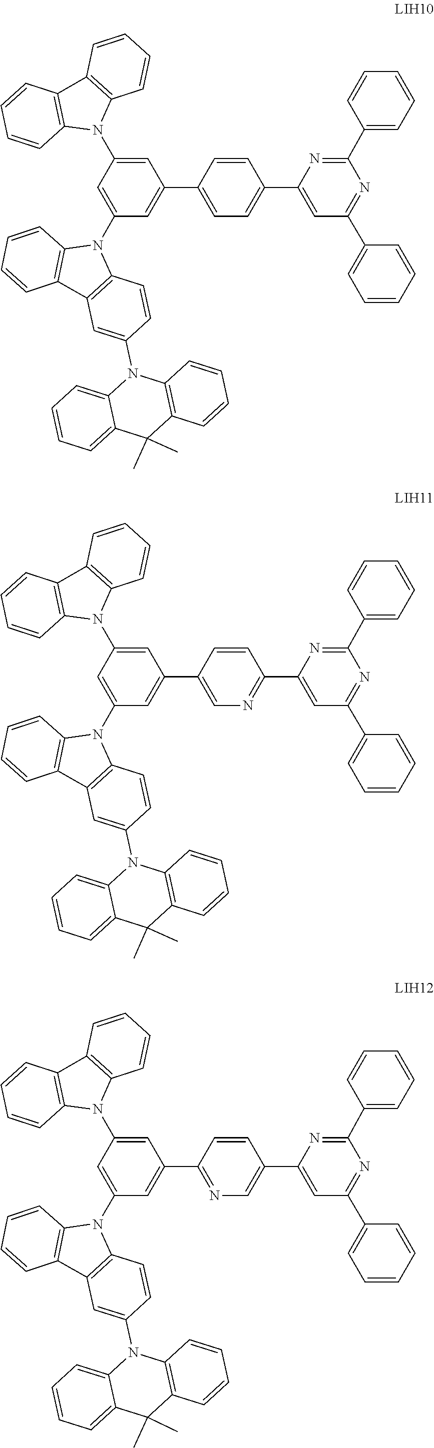 [SMILES: CC1(C)c2ccccc2N(c2ccc3c(c2)c2ccccc2n3-c2cc(-c3ccc(-c4cc(-c5ccccc5)nc(-c5ccccc5)n4)cc3)cc(-n3c4ccccc4c4ccccc43)c2)c2ccccc21 ; CC1(C)c2ccccc2N(c2ccc3c(c2)c2ccccc2n3-c2cc(-c3ccc(-c4cc(-c5ccccc5)nc(-c5ccccc5)n4)nc3)cc(-n3c4ccccc4c4ccccc43)c2)c2ccccc21 ; CC1(C)c2ccccc2N(c2ccc3c(c2)c2ccccc2n3-c2cc(-c3ccc(-c4cc(-c5ccccc5)nc(-c5ccccc5)n4)cn3)cc(-n3c4ccccc4c4ccccc43)c2)c2ccccc21]

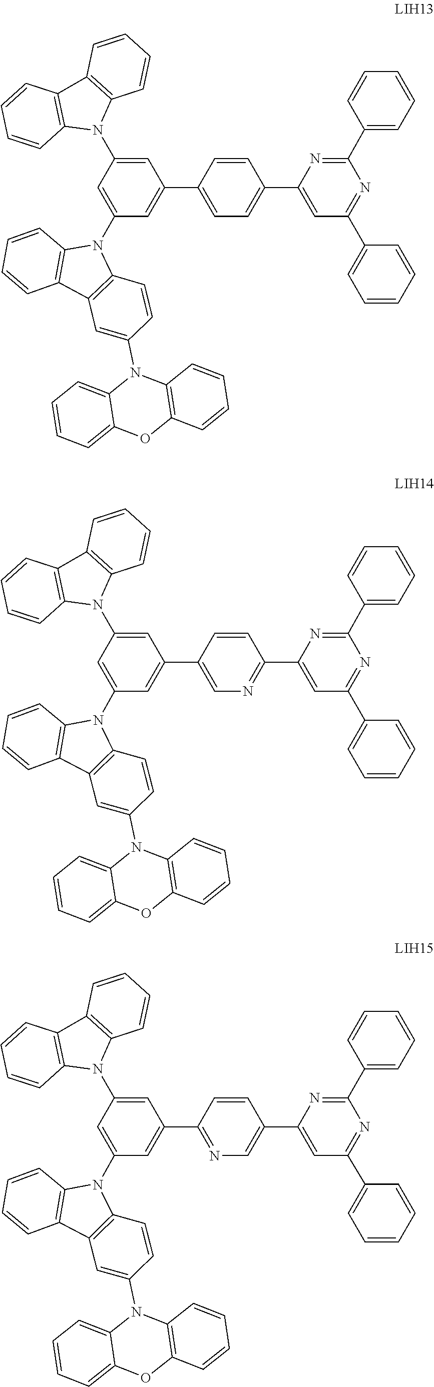 [SMILES: c1ccc(-c2cc(-c3ccc(-c4cc(-n5c6ccccc6c6ccccc65)cc(-n5c6ccccc6c6cc(N7c8ccccc8Oc8ccccc87)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(N7c8ccccc8Oc8ccccc87)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(N7c8ccccc8Oc8ccccc87)ccc65)c4)nc3)nc(-c3ccccc3)n2)cc1]

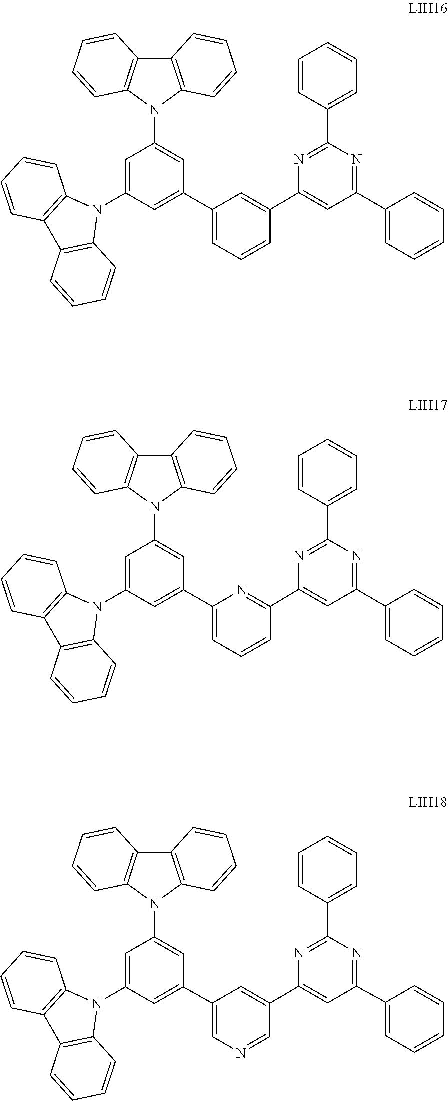 [SMILES: c1ccc(-c2cc(-c3cccc(-c4cc(-n5c6ccccc6c6ccccc65)cc(-n5c6ccccc6c6ccccc65)c4)c3)nc(-c3ccccc3)n2)cc1 ; c1ccc(-c2cc(-c3cccc(-c4cc(-n5c6ccccc6c6ccccc65)cc(-n5c6ccccc6c6ccccc65)c4)n3)nc(-c3ccccc3)n2)cc1 ; c1ccc(-c2cc(-c3cncc(-c4cc(-n5c6ccccc6c6ccccc65)cc(-n5c6ccccc6c6ccccc65)c4)c3)nc(-c3ccccc3)n2)cc1]

For example, when the compound as the second host (LIH) includes a carbazole- and a triazine-based group, the compound may be selected from the following compounds LIH19 to LIH33:

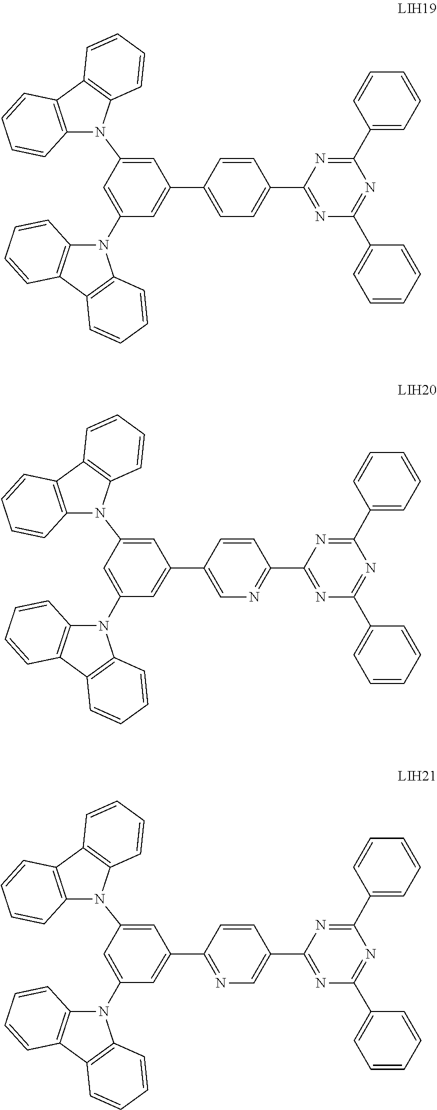 [SMILES: c1ccc(-c2nc(-c3ccccc3)nc(-c3ccc(-c4cc(-n5c6ccccc6c6ccccc65)cc(-n5c6ccccc6c6ccccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)nc3)n2)cc1]

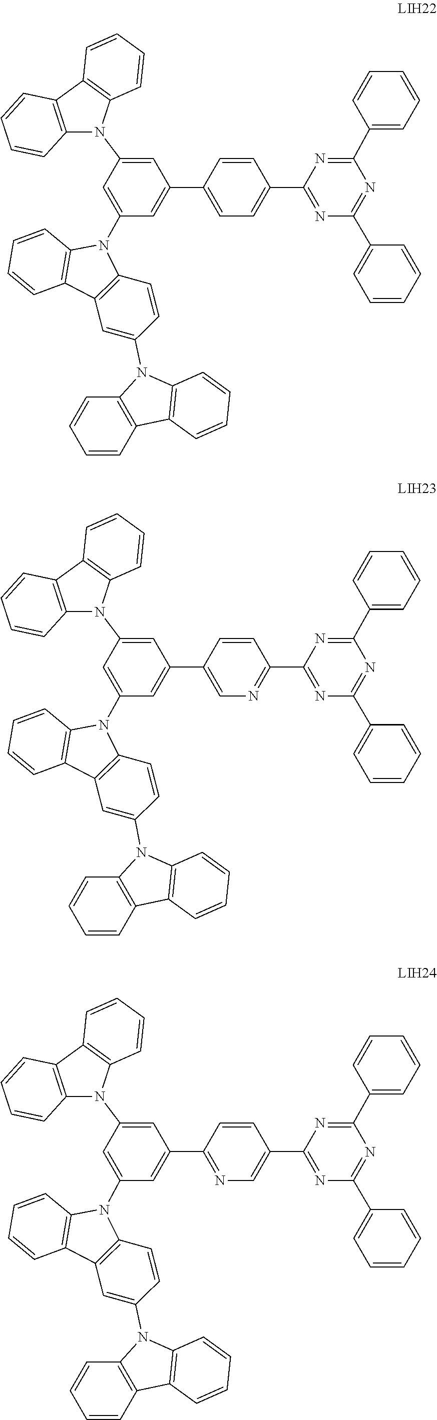 [SMILES: c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)nc3)n2)cc1]

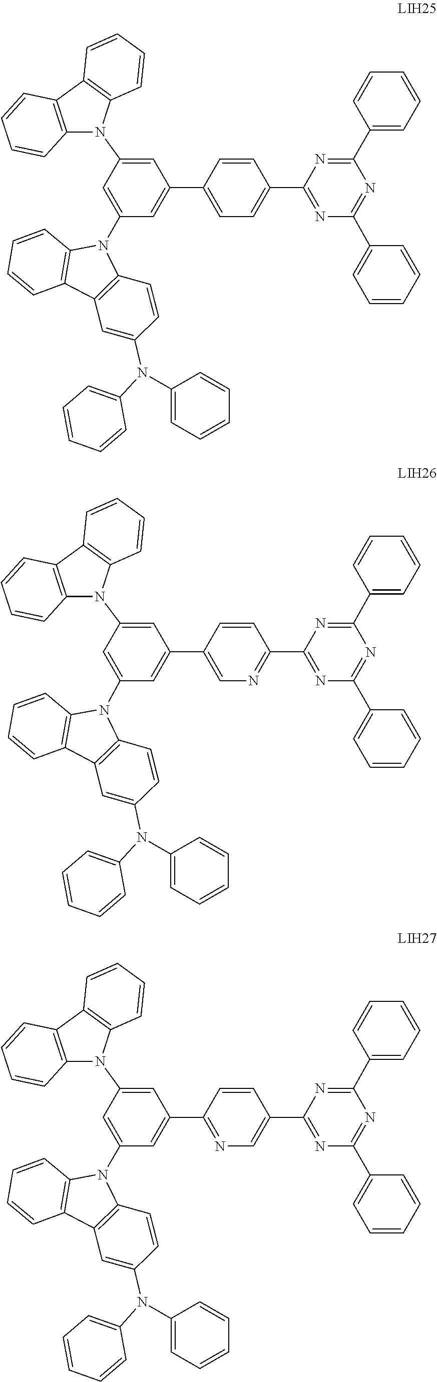 [SMILES: c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)nc3)n2)cc1]

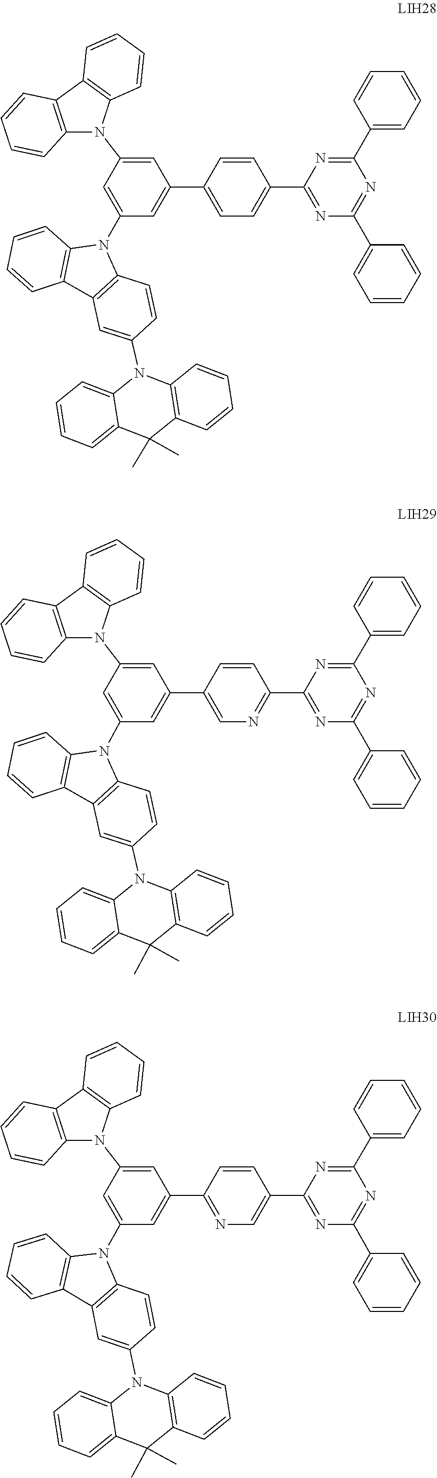 [SMILES: CC1(C)c2ccccc2N(c2ccc3c(c2)c2ccccc2n3-c2cc(-c3ccc(-c4nc(-c5ccccc5)nc(-c5ccccc5)n4)cc3)cc(-n3c4ccccc4c4ccccc43)c2)c2ccccc21 ; CC1(C)c2ccccc2N(c2ccc3c(c2)c2ccccc2n3-c2cc(-c3ccc(-c4nc(-c5ccccc5)nc(-c5ccccc5)n4)nc3)cc(-n3c4ccccc4c4ccccc43)c2)c2ccccc21 ; CC1(C)c2ccccc2N(c2ccc3c(c2)c2ccccc2n3-c2cc(-c3ccc(-c4nc(-c5ccccc5)nc(-c5ccccc5)n4)cn3)cc(-n3c4ccccc4c4ccccc43)c2)c2ccccc21]

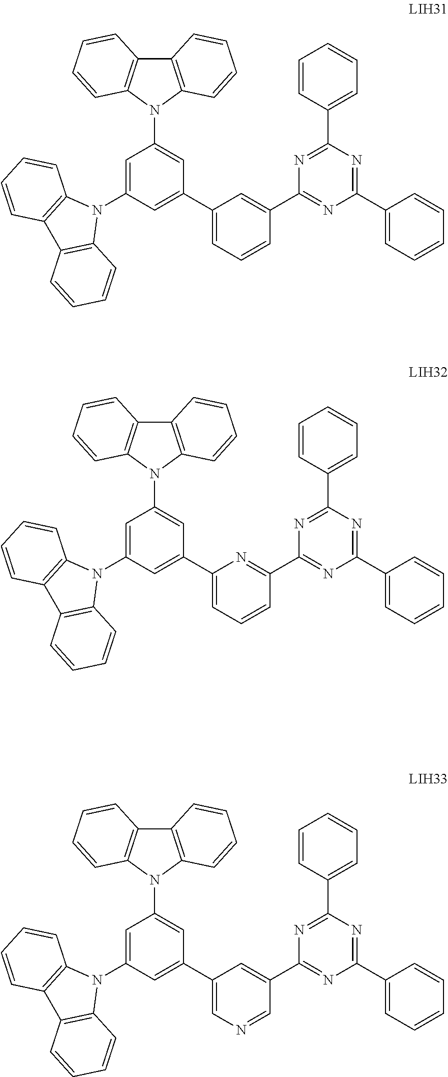 [SMILES: c1ccc(-c2nc(-c3ccccc3)nc(-c3cccc(-c4cc(-n5c6ccccc6c6ccccc65)cc(-n5c6ccccc6c6ccccc65)c4)c3)n2)cc1 ; c1ccc(-c2nc(-c3ccccc3)nc(-c3cccc(-c4cc(-n5c6ccccc6c6ccccc65)cc(-n5c6ccccc6c6ccccc65)c4)n3)n2)cc1 ; c1ccc(-c2nc(-c3ccccc3)nc(-c3cncc(-c4cc(-n5c6ccccc6c6ccccc65)cc(-n5c6ccccc6c6ccccc65)c4)c3)n2)cc1]

In addition, when the compound as the second host (LIH) includes a spirofluorene, a triazine, or a pyrimidine-based group, the compound may be selected from the following compounds LIH34 to LIH45:

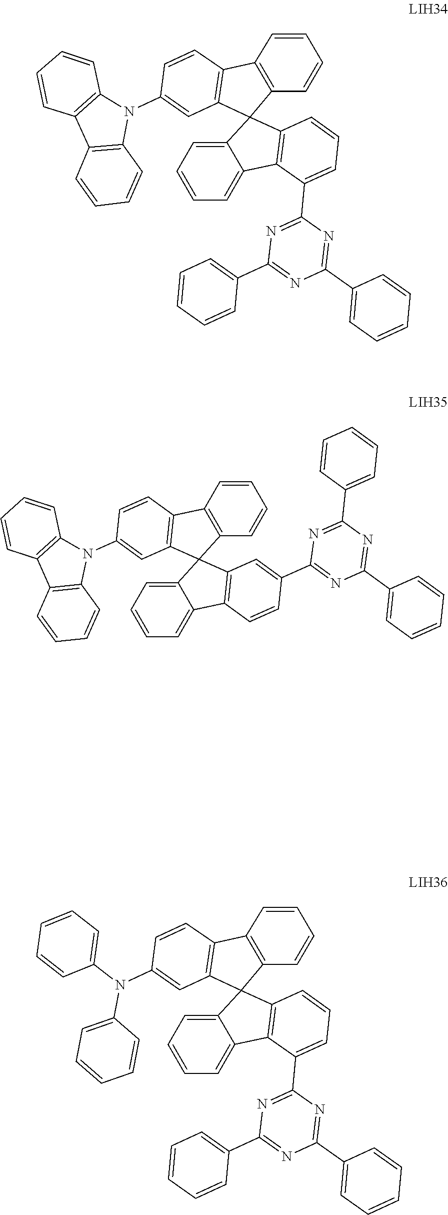 [SMILES: c1ccc(-c2nc(-c3ccccc3)nc(-c3cccc4c3-c3ccccc3C43c4ccccc4-c4ccc(-n5c6ccccc6c6ccccc65)cc43)n2)cc1 ; c1ccc(-c2nc(-c3ccccc3)nc(-c3ccc4c(c3)C3(c5ccccc5-4)c4ccccc4-c4ccc(-n5c6ccccc6c6ccccc65)cc43)n2)cc1 ; c1ccc(-c2nc(-c3ccccc3)nc(-c3cccc4c3-c3ccccc3C43c4ccccc4-c4ccc(N(c5ccccc5)c5ccccc5)cc43)n2)cc1]

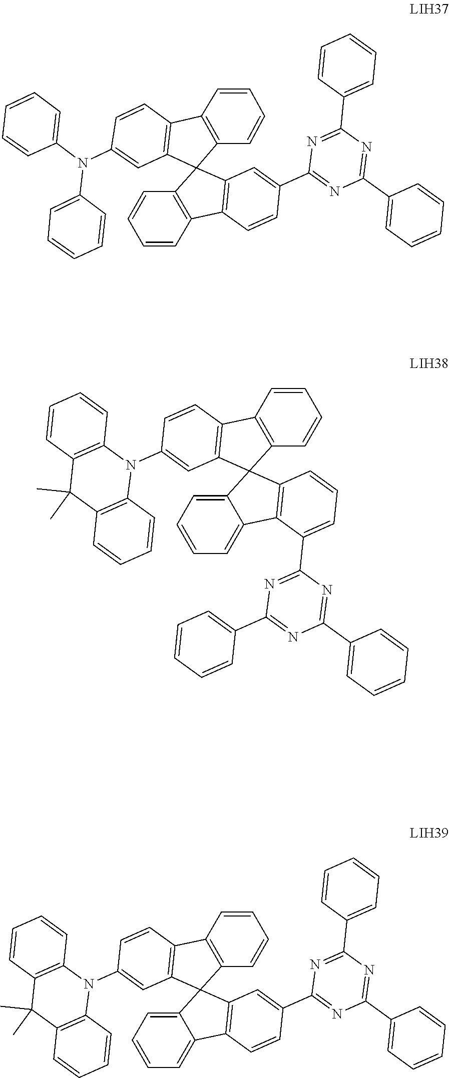 [SMILES: c1ccc(-c2nc(-c3ccccc3)nc(-c3ccc4c(c3)C3(c5ccccc5-4)c4ccccc4-c4ccc(N(c5ccccc5)c5ccccc5)cc43)n2)cc1 ; CC1(C)c2ccccc2N(c2ccc3c(c2)C2(c4ccccc4-3)c3ccccc3-c3c(-c4nc(-c5ccccc5)nc(-c5ccccc5)n4)cccc32)c2ccccc21 ; CC1(C)c2ccccc2N(c2ccc3c(c2)C2(c4ccccc4-c4ccc(-c5nc(-c6ccccc6)nc(-c6ccccc6)n5)cc42)c2ccccc2-3)c2ccccc21]

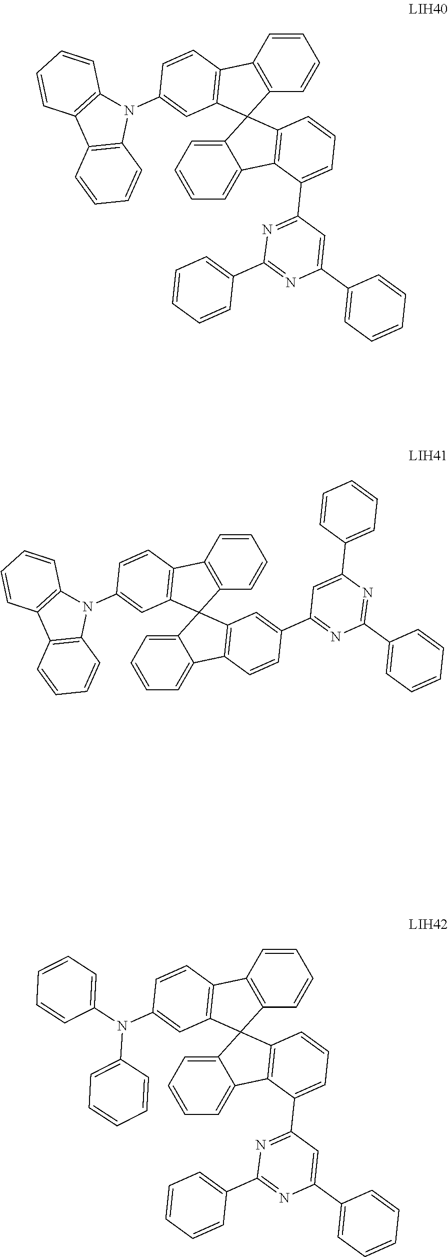 [SMILES: c1ccc(-c2cc(-c3cccc4c3-c3ccccc3C43c4ccccc4-c4ccc(-n5c6ccccc6c6ccccc65)cc43)nc(-c3ccccc3)n2)cc1 ; c1ccc(-c2cc(-c3ccc4c(c3)C3(c5ccccc5-4)c4ccccc4-c4ccc(-n5c6ccccc6c6ccccc65)cc43)nc(-c3ccccc3)n2)cc1 ; c1ccc(-c2cc(-c3cccc4c3-c3ccccc3C43c4ccccc4-c4ccc(N(c5ccccc5)c5ccccc5)cc43)nc(-c3ccccc3)n2)cc1]

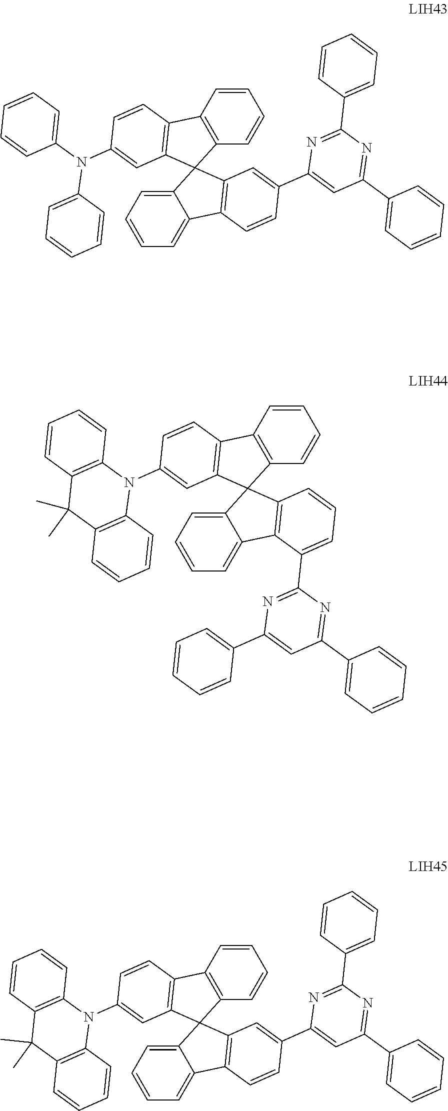 [SMILES: c1ccc(-c2cc(-c3ccc4c(c3)C3(c5ccccc5-4)c4ccccc4-c4ccc(N(c5ccccc5)c5ccccc5)cc43)nc(-c3ccccc3)n2)cc1 ; CC1(C)c2ccccc2N(c2ccc3c(c2)C2(c4ccccc4-3)c3ccccc3-c3c(-c4nc(-c5ccccc5)cc(-c5ccccc5)n4)cccc32)c2ccccc21 ; CC1(C)c2ccccc2N(c2ccc3c(c2)C2(c4ccccc4-c4ccc(-c5cc(-c6ccccc6)nc(-c6ccccc6)n5)cc42)c2ccccc2-3)c2ccccc21]

Alternatively, when the compound as the second host (LIH) includes carbazole and dibenzofuran, the compound may be selected from the following compounds LIH46 to LIH51.

When the compound as the second host (LIH) includes a pyrimidine or a triazine-base group along with linkages between a plurality of carbazole-based groups, the compound may be selected from the following compounds LIH52 to LIH55:

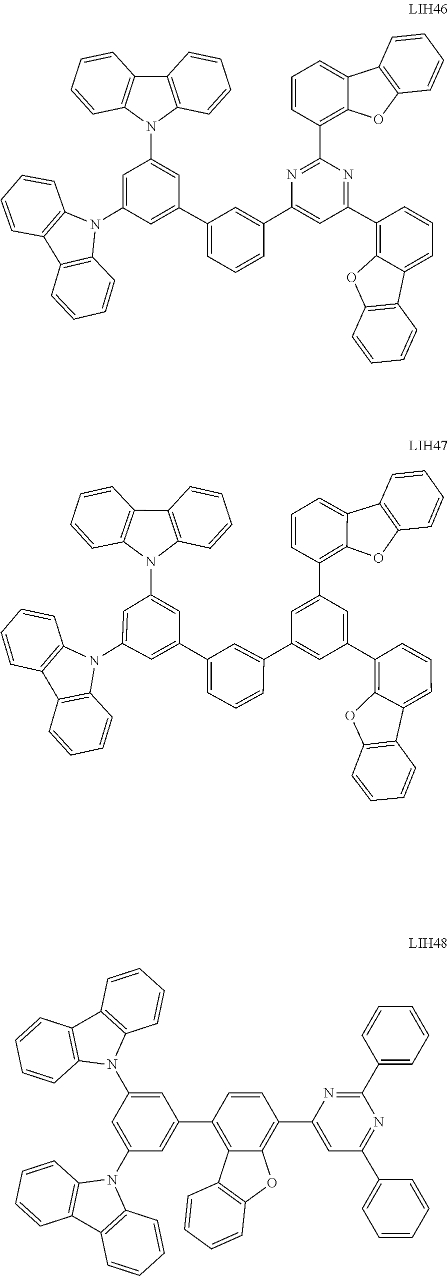 [SMILES: c1cc(-c2cc(-n3c4ccccc4c4ccccc43)cc(-n3c4ccccc4c4ccccc43)c2)cc(-c2cc(-c3cccc4c3oc3ccccc34)nc(-c3cccc4c3oc3ccccc34)n2)c1 ; c1cc(-c2cc(-c3cccc4c3oc3ccccc34)cc(-c3cccc4c3oc3ccccc34)c2)cc(-c2cc(-n3c4ccccc4c4ccccc43)cc(-n3c4ccccc4c4ccccc43)c2)c1 ; c1ccc(-c2cc(-c3ccc(-c4cc(-n5c6ccccc6c6ccccc65)cc(-n5c6ccccc6c6ccccc65)c4)c4c3oc3ccccc34)nc(-c3ccccc3)n2)cc1]

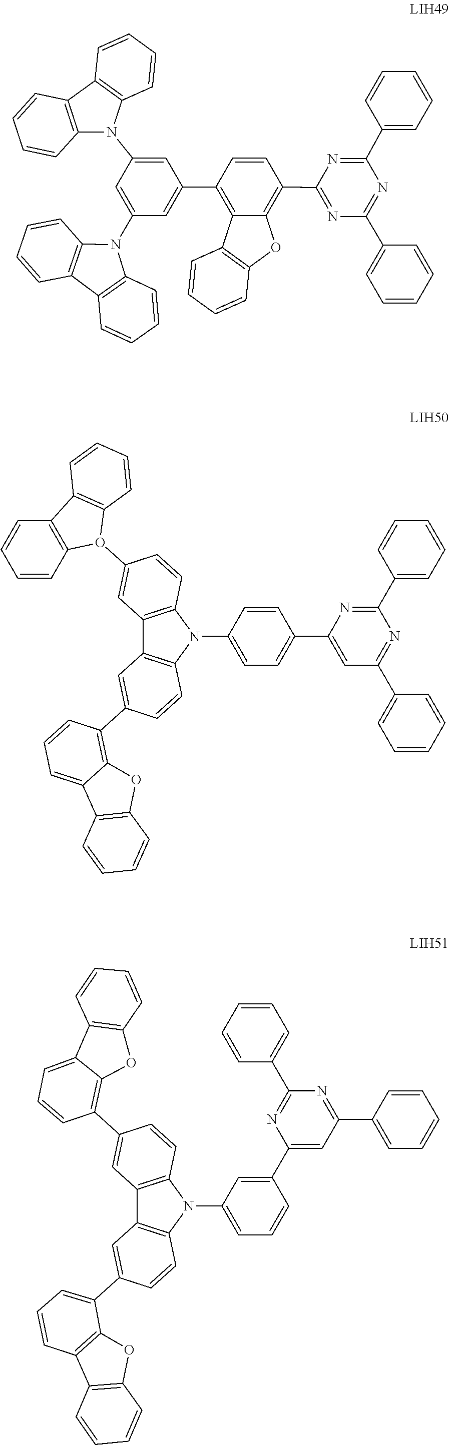

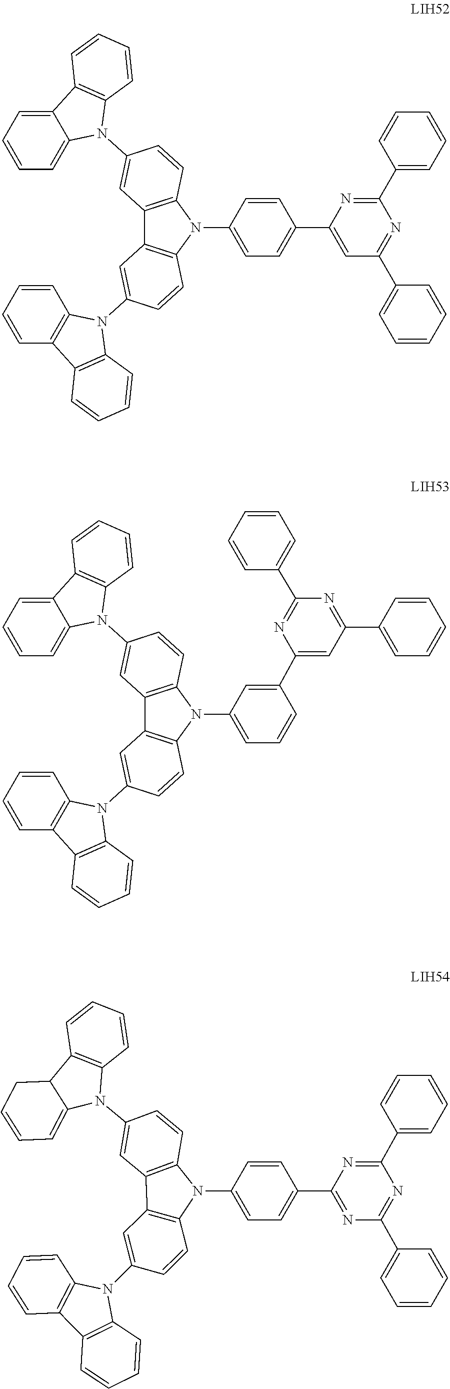 [SMILES: c1ccc(-c2cc(-c3ccc(-n4c5ccc(-n6c7ccccc7c7ccccc76)cc5c5cc(-n6c7ccccc7c7ccccc76)ccc54)cc3)nc(-c3ccccc3)n2)cc1 ; c1ccc(-c2cc(-c3cccc(-n4c5ccc(-n6c7ccccc7c7ccccc76)cc5c5cc(-n6c7ccccc7c7ccccc76)ccc54)c3)nc(-c3ccccc3)n2)cc1 ; C1=CCC2C(=C1)N(c1ccc3c(c1)c1cc(-n4c5ccccc5c5ccccc54)ccc1n3-c1ccc(-c3nc(-c4ccccc4)nc(-c4ccccc4)n3)cc1)c1ccccc12]

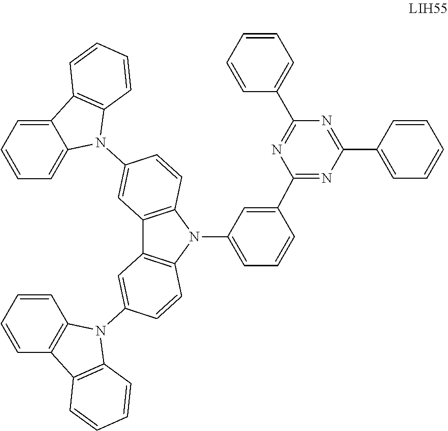 [SMILES: c1ccc(-c2nc(-c3ccccc3)nc(-c3cccc(-n4c5ccc(-n6c7ccccc7c7ccccc76)cc5c5cc(-n6c7ccccc7c7ccccc76)ccc54)c3)n2)cc1]

Meanwhile, the above-mentioned materials of the second host LIH are provided as examples of a bipolar material and the light emitting device of the present disclosure is not limited thereto. Any material may be used instead of the compounds illustrated above so long as it is stable and bipolar.

In addition, the efficiency-improving layer 160 performs auxiliary light emission E2 and the second blue light emitting dopant BD2 therefor may be selected from HBD1 to HBD24 as follows:

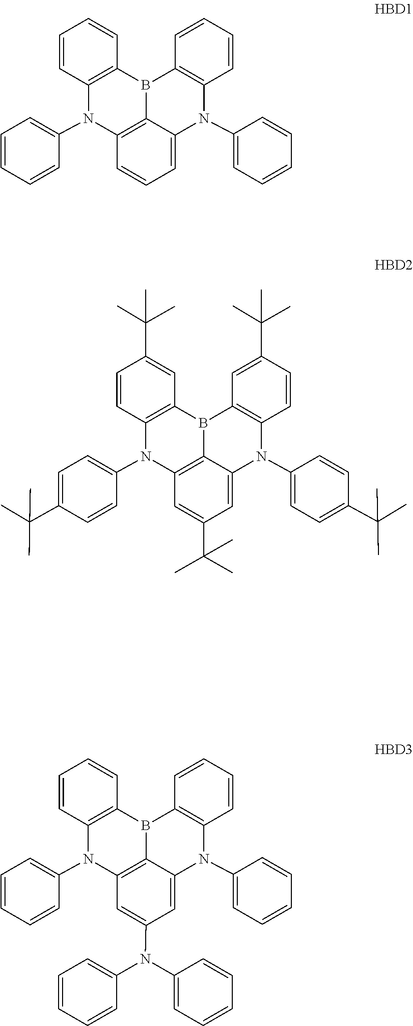 [SMILES: c1ccc(N2c3ccccc3B3c4ccccc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1 ; c1ccc(N(c2ccccc2)c2cc3c4c(c2)N(c2ccccc2)c2ccccc2B4c2ccccc2N3c2ccccc2)cc1]

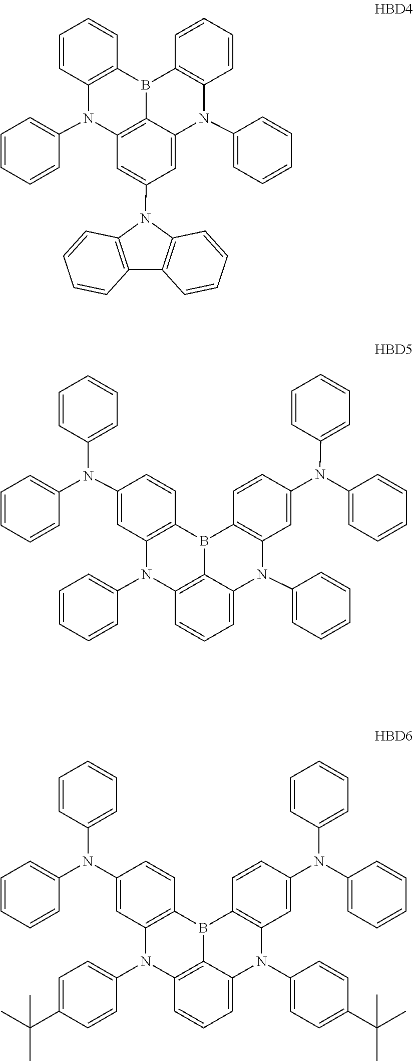 [SMILES: c1ccc(N2c3ccccc3B3c4ccccc4N(c4ccccc4)c4cc(-n5c6ccccc6c6ccccc65)cc2c43)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3cc(N(c4ccccc4)c4ccccc4)ccc3B3c4ccc(N(c5ccccc5)c5ccccc5)cc4N(c4ccc(C(C)(C)C)cc4)c4cccc2c43)cc1]

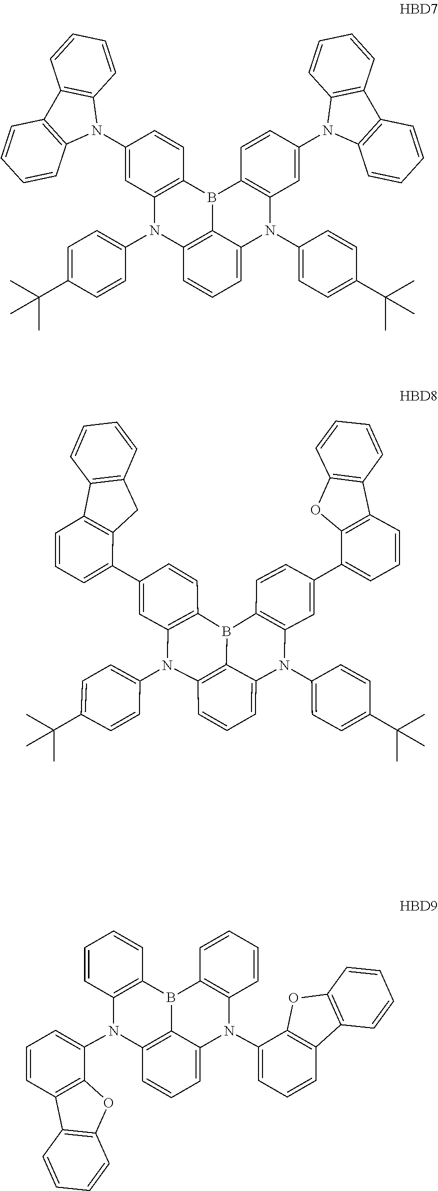 [SMILES: CC(C)(C)c1ccc(N2c3cc(-n4c5ccccc5c5ccccc54)ccc3B3c4ccc(-n5c6ccccc6c6ccccc65)cc4N(c4ccc(C(C)(C)C)cc4)c4cccc2c43)cc1 ; CC(C)(C)c1ccc(N2c3cc(-c4cccc5c4Cc4ccccc4-5)ccc3B3c4ccc(-c5cccc6c5oc5ccccc56)cc4N(c4ccc(C(C)(C)C)cc4)c4cccc2c43)cc1 ; c1ccc2c(c1)B1c3ccccc3N(c3cccc4c3oc3ccccc34)c3cccc(c31)N2c1cccc2c1oc1ccccc12]

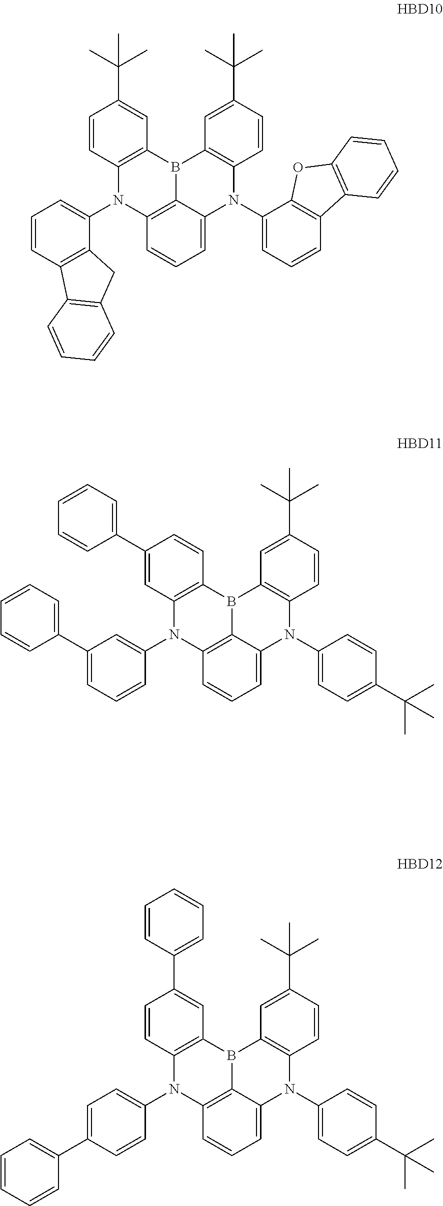 [SMILES: CC(C)(C)c1ccc2c(c1)B1c3cc(C(C)(C)C)ccc3N(c3cccc4c3oc3ccccc34)c3cccc(c31)N2c1cccc2c1Cc1ccccc1-2 ; CC(C)(C)c1ccc(N2c3ccc(C(C)(C)C)cc3B3c4ccc(-c5ccccc5)cc4N(c4cccc(-c5ccccc5)c4)c4cccc2c43)cc1 ; CC(C)(C)c1ccc(N2c3ccc(C(C)(C)C)cc3B3c4cc(-c5ccccc5)ccc4N(c4ccc(-c5ccccc5)cc4)c4cccc2c43)cc1]

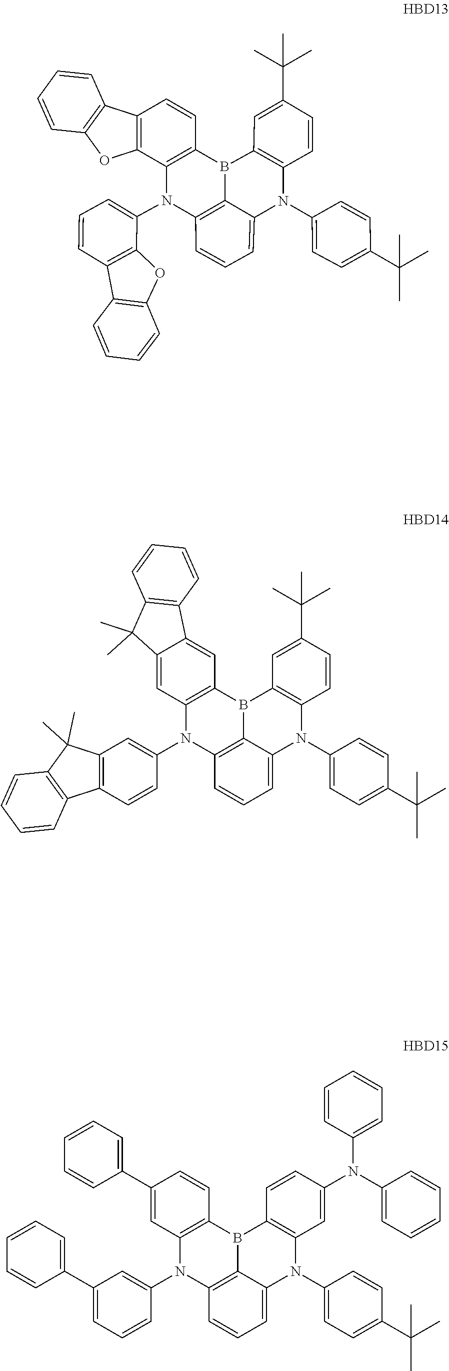 [SMILES: CC(C)(C)c1ccc(N2c3ccc(C(C)(C)C)cc3B3c4ccc5c(oc6ccccc65)c4N(c4cccc5c4oc4ccccc45)c4cccc2c43)cc1 ; CC(C)(C)c1ccc(N2c3ccc(C(C)(C)C)cc3B3c4cc5c(cc4N(c4ccc6c(c4)C(C)(C)c4ccccc4-6)c4cccc2c43)C(C)(C)c2ccccc2-5)cc1 ; CC(C)(C)c1ccc(N2c3cc(N(c4ccccc4)c4ccccc4)ccc3B3c4ccc(-c5ccccc5)cc4N(c4cccc(-c5ccccc5)c4)c4cccc2c43)cc1]

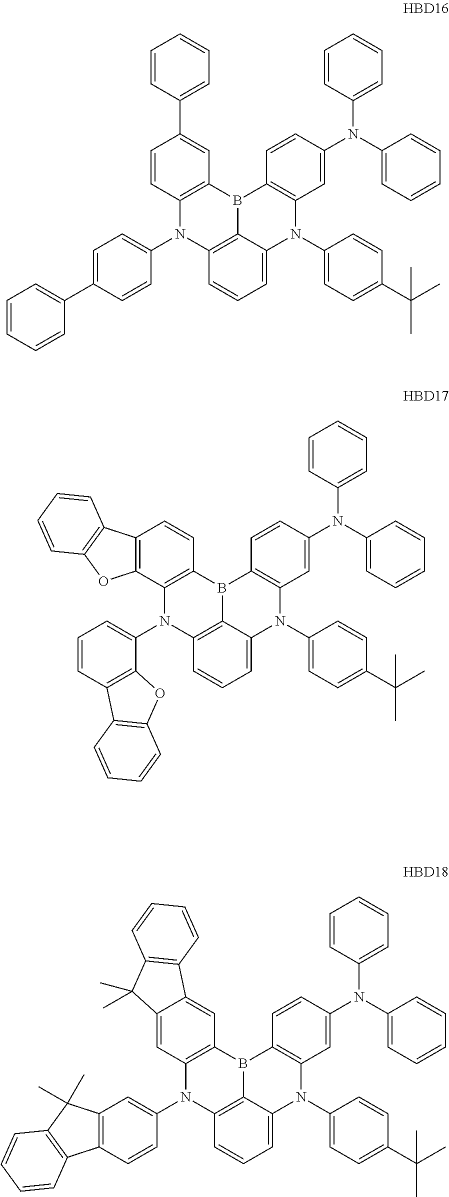 [SMILES: CC(C)(C)c1ccc(N2c3cc(N(c4ccccc4)c4ccccc4)ccc3B3c4cc(-c5ccccc5)ccc4N(c4ccc(-c5ccccc5)cc4)c4cccc2c43)cc1 ; CC(C)(C)c1ccc(N2c3cc(N(c4ccccc4)c4ccccc4)ccc3B3c4ccc5c(oc6ccccc65)c4N(c4cccc5c4oc4ccccc45)c4cccc2c43)cc1 ; CC(C)(C)c1ccc(N2c3cc(N(c4ccccc4)c4ccccc4)ccc3B3c4cc5c(cc4N(c4ccc6c(c4)C(C)(C)c4ccccc4-6)c4cccc2c43)C(C)(C)c2ccccc2-5)cc1]

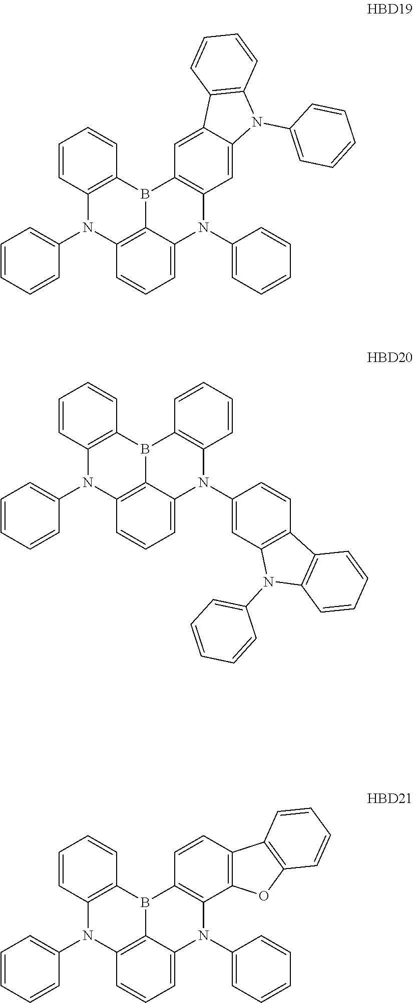 [SMILES: c1ccc(N2c3ccccc3B3c4cc5c6ccccc6n(-c6ccccc6)c5cc4N(c4ccccc4)c4cccc2c43)cc1 ; c1ccc(N2c3ccccc3B3c4ccccc4N(c4ccc5c6ccccc6n(-c6ccccc6)c5c4)c4cccc2c43)cc1 ; c1ccc(N2c3ccccc3B3c4ccc5c(oc6ccccc65)c4N(c4ccccc4)c4cccc2c43)cc1]

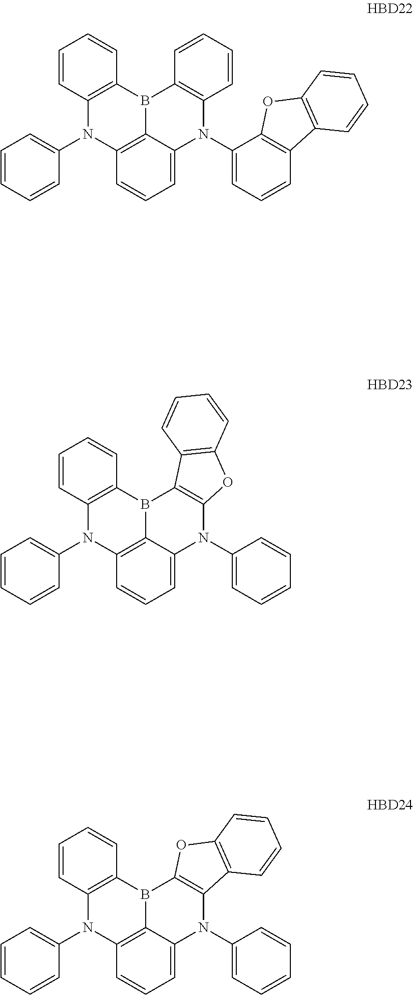 [SMILES: c1ccc(N2c3ccccc3B3c4ccccc4N(c4cccc5c4oc4ccccc45)c4cccc2c43)cc1 ; c1ccc(N2c3ccccc3B3c4c2cccc4N(c2ccccc2)c2oc4ccccc4c23)cc1 ; c1ccc(N2c3ccccc3B3c4oc5ccccc5c4N(c4ccccc4)c4cccc2c43)cc1]

Meanwhile, the second dopant (BD2) is, for example, a compound containing boron as a core. The dopant may also be used as the first dopant BD1 in the light emitting layer 150.

However, the present disclosure is not limited thereto. The second dopant BD2 may be a fluorescent dopant having an energy band gap of 2.65 eV or more, a TADF dopant, or a phosphorescent dopant, in addition to the examples of dopant described above. The second host LIH used in the efficiency-improving layer 160 has a large energy bandgap, so a variety of dopants may be used.

HBD1 to HBD24 may be used as the dopant in both the light emitting layer 150 and the efficiency-improving layer 160.

If the first blue light emitting dopant BD1 of the light emitting layer 150 is different from the second blue light emitting dopant BD2 of the efficiency-improving layer 160, the triplet level of the second blue light emitting dopant of the efficiency-improving layer 160 is higher than the triplet level of the first blue light emitting dopant of the light emitting layer (T₁(BD in HRL)>T₁(BD in B EML)), and the singlet level of the second blue light emitting dopant of the efficiency-improving layer is higher than the singlet level of the first blue light emitting dopant of the light emitting layer (S₁(BD2 in HRL)>S₁(BD1 in B EML)), to transfer energy through the efficiency-improving layer 160 so as to cause main light emission in the light emitting layer 150.

Accordingly, the efficiency-improving layer 160 functions to perform the auxiliary light emission E2, in addition to the main light emission E1 by the light emitting layer 150.

The electron transport layer 170 is a layer to transport electrons from the second electrode 200 to the light emitting layer 150 through the efficiency-improving layer 160 and may include a derivative containing anthracene as a core.

In addition, the electron injection layer 180 may be a layer that includes LiF, Liq, a transition metal, or the like and thus facilitates injection of electrons from the second electrode 200.

In the example illustrated with reference to FIGS. 1 to 3, the first electrode 110 is also referred to as an “anode” and the second electrode 200 is also referred to as a “cathode”.

The directions of the main light emission E1 by the light emitting layer 150 and the auxiliary light emission E2 by the efficiency-improving layer 160 shown in FIG. 3 are provided when the first electrode 110 and the second electrode 200 correspond to a transparent electrode and a reflective electrode, respectively. However, the present disclosure is not limited thereto and light emission may occur in the opposite direction.

Also, FIG. 1 shows an example in which the electron-blocking layer 140 is provided on the side opposite to the side of the light emitting layer 150 that contacts the efficiency-improving layer 160. In some cases, the electron-blocking layer 140 may be omitted, such that the light emitting layer 150 and the hole transport layer 130 directly contact each other. In the example shown in FIG. 2, the LUMO level of the hole transport layer 130 is higher than the LUMO level of the light emitting layer 150 and the hole transport layer 130 may also have an electron blocking function.

Meanwhile, a configuration including the hole transport layer 130, the electron-blocking layer 140, the light emitting layer 150, the efficiency-improving layer 160, and the electron transport layer 170 is referred to as a blue light emitting unit BU. In addition, the blue light emitting unit BU may be connected to another light emitting unit via a charge-generating layer interposed between the first electrode 110 and the second electrode 200.

Hereinafter, the effect of the light emitting device of the present disclosure will be described with reference to an example in which the material of the efficiency-improving layer, the thickness of the adjacent light emitting layer and the thickness of the electron transport layer are changed.

The first to seventh experimental examples (Ex1 to Ex7) were performed and a light emitting device was formed in the order of the structure shown in FIG. 1.

A first electrode (anode) of ITO was formed on a substrate, was cleaned with UV and ozone, and then loaded into an evaporation system.

Then, the first electrode (anode) was transferred into a vacuum deposition chamber so as to deposit each component on the first electrode (anode).

The deposition was performed by evaporation from a heating boat under vacuum of about 10⁻⁶ ton in the following process.

This process will be described with reference to the first experimental example (Ex1).

That is, a hole injection layer (HIL) was formed to a thickness of 110 Å using DNTPD along with MgF₂. Then, a hole transport layer (HTL) having a thickness of 600 Å was formed using DNTPD.

Then, an electron-blocking layer (EBL) was formed to a thickness of 150 Å using TATC.

Then, MADN, as a first host (BH), was doped at 2 wt % with HBD1 as a first blue light emitting dopant (BD1) to form a light emitting layer (BEML) having a thickness of 300 Å.

Then, an electron transport layer (ETL) was formed to a thickness of 230 Å using ZADN.

Then, an electron injection layer (EIL) was formed to a thickness of 15 Å using LiF.

Then, a second electrode (cathode) was formed using aluminum (Al).

The first and second experimental examples (Ex1, Ex2) have no efficiency-improving layer, the first experimental example (Ex1) is an example in which the efficiency in the light emitting layer is further considered, and the second experimental example (Ex2) is an example in which the lifespan is further considered and thus the HOMO/LUMO energy level of the material of the electron-blocking layer (EBL) in contact with the light emitting layer is adjusted. Table 1 shows the values of other experimental examples evaluated based on the driving voltage, luminance efficiency, external quantum efficiency, color coordinate values (CIEx, CIEy) and lifespan of the second experimental example (Ex2).

In the second experimental example (Ex2), the hole current of the electron-blocking layer (EBL) was improved compared to the first experimental example (Ex1), a wider light emitting area was formed in the light emitting layer (B EML), and thus the lifespan was improved compared to the first experimental example (Ex1).

The first experimental example (Ex1) was designed in consideration of efficiency compared to lifespan and the lifespan of the first experimental example (Ex1) was set at a level of 65% compared to that of the second experimental example (Ex2).

In the third experimental example (Ex3) to the fifth experimental example (Ex5), the efficiency-improving layer 160 was provided and LIH1 to LIH55 were used as the second host LIH for the efficiency-improving layer 160. In addition, the second blue light emitting dopant BD2 included the same HBD1 as the first blue light emitting dopant BD1 of the light emitting layer.

In the third experimental example (Ex3), the thickness of the light emitting layer 150 was set to 200 Å, the thickness of the efficiency-improving layer 160 was set to 100 Å, and the thickness of the electron transport layer 170 was set to 230 Å.

In the fourth experimental example (Ex4), the thickness of the light emitting layer 150 was set to 150 Å, the thickness of the efficiency-improving layer 160 was set to 150 Å, and the thickness of the electron transport layer 170 was set to 230 Å.

In the fifth experimental example (Ex5), the thickness of the light emitting layer 150 was set to 300 Å, the thickness of the efficiency-improving layer 160 was set to 100 Å, and the thickness of the electron transport layer 170 was set to 130 Å.

The sixth experimental example (Ex6) is different from the third experimental example (Ex3) merely in that the host material in the efficiency-improving layer is an N-type single component, the thickness of other components is the same, and the configuration of the adjacent layer is the same. For example, the N-type single component used herein was a triazine derivative.

In the seventh experimental example (Ex7), compared to the third experimental example (Ex3) described above, the host material in the efficiency-improving layer was a mixture of an N-type host and a P-type host at a ratio of 1:1, and the other conditions were the same as in the third experimental example (Ex3). The N-type host used herein was a triazine derivative and the P-type host used herein was mCBP.

These experimental examples will be described based on Table 1.

Table 1 shows the device characteristics at 10 mA/cm², and illustrates that the third experimental example (Ex3), the fifth experimental example (Ex5), and the seventh experimental example (Ex7) exhibit improved lifespan and the third to sixth experimental experiments (Ex3 to Ex6) exhibit improved efficiency.

TABLE 1

| | Structure (B | | | Luminance | | | | |
|---|---|---|---|---|---|---|---|---|
| Experimental | EML/HRL/ETL): | | Voltage | efficiency | | | | |
| Examples | thickness (Å) | | (V) | (Cd/A) | EQE | CIEx | CIEy | Lifespan |
| Ex1 | 300/0/230 | (Å) | +0.06 | 104% | 105% | 0.000 | −0.002 | 65% |
| Ex2 | 300/0/230 | (Å) | 0.00 | 100% | 100% | — | — | 100% |
| Ex3 | 200/100/230 | (Å) | +0.08 | 105% | 105% | 0.001 | 0.001 | 124% |
| Ex4 | 150/150/230 | (Å) | +0.12 | 102% | 100% | 0.001 | 0.001 | 83% |
| Ex5 | 300/100/130 | (Å) | +0.02 | 102% | 100% | 0.000 | 0.004 | 120% |
| Ex6 | 200/100/230 | (Å) | +0.10 | 105% | 104% | 0.000 | 0.002 | 60% |
| Ex7 | 200/100/230 | (Å) | +0.18 | 91% | 89% | 0.000 | 0.004 | 136% |

The first and second experimental examples Ex1 and Ex2 are examples in which the efficiency-improving layer is not provided. In addition, in the second experimental example (Ex2), the HOMO/LUMO level of the electron-blocking layer was changed in consideration of the lifespan, and the driving voltage was decreased by 0.06V compared to the first experimental example (Ex1) because the hole current was increased.

Also, the third experimental example (Ex3) has a luminance efficiency of 105% and an external quantum efficiency of 105% compared to the second experimental example (Ex2), and in particular, the lifespan is 124%, which means that the effects of improving the efficiency and lifespan are remarkable. This also means that the formation of excitons by extra holes occurs very efficiently in the efficiency-improving layer HRL.

In the fourth experimental example (Ex4), the efficiency-improving layer (HRL) includes the same second host material and the second blue light emitting dopant (BD2) as in the third experimental example (Ex3), but the thickness of the efficiency-improving layer (HRL) is slightly increased and the thickness of the light emitting layer (B EML) was decreased. In this case, in the fourth experimental example (Ex4), both lifespan and efficiency were reduced. This is because the second host (LIH) used in the efficiency-improving layer (HRL) has slightly lower exciton formation efficiency and poor thermal stability, compared to the first host (BH) used in the light emitting layer (B EML).

In the fifth experimental example (Ex5), the thickness of the light emitting layer (B EML) was used at the same level as that of the first experimental example (Ex1), and the efficiency-improving layer (HRL) was disposed in the region corresponding to the electron transport layer (ETL) instead. As a result, a lifespan comparable to the third experimental example (Ex3) was obtained, but the efficiency was slightly lowered. This means that, as the efficiency-improving layer (HRL) becomes farther from the interface between the light emitting layer (B EML) and the electron-blocking layer (EBL), generation of excitons by the efficiency-improving layer (HRL) becomes more difficult, and the efficiency-improving layer (HRL) merely has a function of preventing deterioration of the electron transport layer due to holes.

Therefore, in the fourth and fifth experimental examples (Ex4 and Ex5), when the efficiency-improving layer (HRL) is used, it preferably shares a part of the light emitting region with the light emitting layer (B EML). Comparing the third experimental example (Ex3) with the fourth experimental example (Ex4), it can be seen that the efficiency-improving layer (HRL) must have a smaller thickness than the light emitting layer (B EML) so that it is effective in improving the lifespan.

Meanwhile, the sixth experimental example (Ex6) has the same thickness conditions as the third experimental example (Ex3), and the host material of the efficiency-improving layer (HRL) includes an N-type host and a blue light emitting dopant. In this case, the efficiency-improving layer is present in an electron transport path. Compared to the third experimental example (Ex3), the efficiency is similar, but the lifespan is sharply decreased. This is because an N-type polar single host has low durability against holes. Meanwhile, a P-type polar single host opposite to the N-type polar single host has no electron transport ability. When the P-type polar single host is used for the efficiency-improving layer, the material between the electron transport layer and the light emitting layer loses the electron transport ability, so the driving voltage may be excessively increased. Therefore, the P-type polar single host was not evaluated.

The seventh experimental example (Ex7) uses a mixture of a P-type host and an N-type host in a ratio of 3:7. In this case, the lifespan improvement effect is excellent, but the driving voltage increases, and the luminance efficiency and external quantum efficiency decrease conversely. This means that the electron injection ability from the electron transport layer to the light emitting layer is deteriorated.

That is, in the light emitting device of the present disclosure, as in the third experimental example (Ex3), the second host (LIH) of LIH1 to LIH55 and a blue light emitting dopant are used for the efficiency-improving layer, the thickness of the light emitting layer (B EML) is greater than that of the efficiency-improving layer (HRL) and the thickness of the electron transport layer (ETL) is greater than the thickness of the light emitting layer (B EML), so lifespan and efficiency can be remarkably improved compared to the structure not using the efficiency-improving layer.

Accordingly, it can be seen that the light emitting device according to the present disclosure includes an efficiency-improving layer between the light emitting layer and the electron transport layer, wherein efficiency can be improved by inducing auxiliary light emission under the controlled thickness and component conditions and lifespan can be improved using surplus holes. That is, the light emitting device of the present disclosure prevents the trade-off between efficiency and lifespan, which is the problem of blue light emitting devices, and exhibits improved lifespan and efficiency.

The first experimental example (Ex1) uses an electron transport layer having high electron transport ability and causes electron accumulation at the interface between the light emitting layer and the electron-blocking layer, thus providing advantages of realizing TTF activation and efficiency improvement. However, the first experimental example (Ex1) has disadvantages of accelerating the deterioration of the electron-blocking layer and thus shortening the lifespan. The present disclosure is capable of preventing deterioration of the electron-blocking layer and improving efficiency. The present disclosure is capable of solving the general limitation of blue fluorescent devices, namely, the trade-off between lifespan and efficiency.

Meanwhile, the light emitting device emits blue light and is provided in each blue subpixel on the substrate. In this case, the light emitting device is connected to the thin film transistor in the subpixel on the substrate and selectively turns the subpixel on or off.

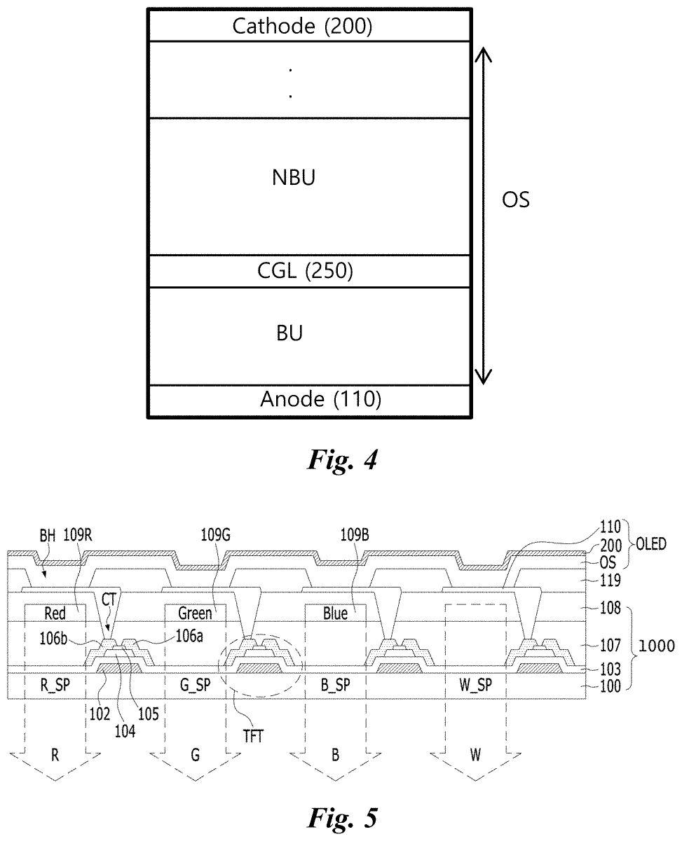

FIG. 4 is a cross-sectional view illustrating a light emitting device according to another embodiment of the present disclosure.

FIG. 4 illustrates a configuration in which a structure including the hole transport layer 130, the electron-blocking layer 140, the light emitting layer 150, the efficiency-improving layer 160, and the electron transport layer 170 described in the structure of the light emitting device of FIG. 3 is defined as a blue light emitting unit (BU), and the blue light emitting unit BU is connected to a non-blue light emitting unit NBU via a charge generation layer 250 interposed between the first electrode 110 and the second electrode 200.

The non-blue light emitting unit NBU may include another light emitting layer and may further include a hole transport layer below the light emitting layer and an electron transport layer above the light emitting layer.

In addition, white light formed by combining the light emitted from the blue light emitting unit BU with the non-blue light emitting unit NBU may be emitted through either the first electrode 110 or the second electrode 200.

In some cases, another light emitting unit may be further added between the non-blue light emitting unit NBU and the second electrode 200 to improve efficiency and color gamut.

An example of a light emitting display device using the light emitting device shown in FIG. 4, to which a plurality of stacks is used between the first electrode and the second electrode, will be described.

Hereinafter, a light emitting display device using the light emitting device according to an embodiment of the present disclosure will be described.

FIG. 5 is a sectional view illustrating the light emitting display device according to an embodiment of the present disclosure.

As shown in FIG. 5, the light emitting display device of the present disclosure includes a substrate 100 having a plurality of subpixels R_SP, G_SP, B_SP, and W_SP, a light emitting device (also referred to as an “OLED, organic light emitting diode”) commonly provided on the substrate 100, a thin film transistor (TFT) provided in each of the subpixels and connected to the first electrode 110 of the light emitting device (OLED), and a color filter layer 109R, 109G, or 109B provided below the first electrode 110 of at least one of the subpixels.

The illustrated example relates to a configuration including the white subpixel W_SP, but the present disclosure is not limited thereto. A configuration in which the white subpixel W_SP is omitted and only the red, green, and blue subpixels R_SP, G_SP, and B_SP are provided is also possible. In some cases, a combination of a cyan subpixel, a magenta subpixel, and a yellow subpixel capable of creating white may be used instead of the red, green, and blue subpixels.

The thin film transistor TFT includes, for example, a gate electrode 102, a semiconductor layer 104, and a source electrode 106a and a drain electrode 106b connected to respective sides of the semiconductor layer 104. In addition, a channel passivation layer 105 may be further provided on the portion where the channel of the semiconductor layer 104 is located in order to prevent direct connection between the source/drain electrodes 106a and 106b and the semiconductor layer 104.

A gate insulating layer 103 is provided between the gate electrode 102 and the semiconductor layer 104.

The semiconductor layer 104 may be formed of, for example, an oxide semiconductor, amorphous silicon, polycrystalline silicon, or a combination thereof. For example, when the semiconductor layer 104 is an oxide semiconductor, the heating temperature for forming the thin film transistor can be lowered, and thus the substrate 100 can be selected from among a greater variety of available types thereof, so the semiconductor layer 104 can be advantageously applied to a flexible display.

In addition, the drain electrode 106b of the thin film transistor TFT may be connected to the first electrode 110 in a contact hole CT formed in the first and second passivation layers 107 and 108.

The first passivation layer 107 is provided to primarily protect the thin film transistor TFT, and color filter layers 109R, 109G, and 109B may be provided thereon.

When the plurality of subpixels includes a red subpixel, a green subpixel, a blue subpixel, and a white subpixel, the color filter layer may include first to third color filter layers 109R, 109G, and 109B in each of the remaining subpixels, excluding the white subpixel W_SP, and may allow the emitted white light to pass through the first electrode 110 for each wavelength. A second passivation layer 108 is formed under the first electrode 110 to cover the first to third color filter layers 109R, 109G, and 109B. The first electrode 110 is formed on the surface of the second passivation layer 108, excluding the contact hole CT.

Here, the configuration including the substrate 100, the thin film transistor TFT, color filter layers 109R, 109G, and 109B, and the first and second passivation layers 107 and 108 is referred to as a “thin film transistor array substrate” 1000.

Meanwhile, the light emitting device (OLED) improves the efficiency of blue light emission through auxiliary light emission in the efficiency-improving layer adjacent to the (blue) light emitting layer, and reuses the holes, which are consumed only in the light emitting layer in the efficiency-improving layer, for light emission. As a result, the light emitting device (OLED) is capable of increasing the utilization of carriers in the light emitting layer, solving problems such as quenching caused by accumulation of carriers in the light emitting layer and thereby improving the lifespan.

The light emitting device of the present disclosure includes an efficiency-improving layer between the light emitting layer and the electron transport layer, and includes a bipolar host and a blue light emitting dopant in the efficiency-improving layer. That is, the efficiency can be improved using holes, which are not used to generate triplets, for light emission in the efficiency-improving layer in a triplet fusion manner for increasing the efficiency.

In addition, when excitons or carriers are not used for light emission in the light emitting layer and remain quenched therein, the lifespan may be reduced. However, the light emitting device of the present disclosure utilizes surplus holes in the efficiency-improving layer adjacent to the light emitting layer, while the driving current is supplied, thereby preventing lifespan deterioration caused by accumulation of carriers or excitons at the interface, and improving the lifespan.

The light emitting device of the present disclosure has the following effects.

The light emitting device of the present disclosure includes an efficiency-improving layer between the light emitting layer and the electron transport layer, and includes a bipolar host and a blue light emitting dopant in the efficiency-improving layer, to cause auxiliary light emission using, for light emission, the holes remaining in the light emitting layer in the efficiency-improving layer. That is, the efficiency can be improved using holes, which are not used to generate triplets, for light emission in the efficiency-improving layer in a triplet fusion manner for increasing the efficiency.

In addition, when excitons or carriers are not used for light emission in the light emitting layer and remain quenched therein, the lifespan may be reduced. The light emitting device of the present disclosure utilizes surplus holes in the efficiency-improving layer adjacent to the light emitting layer, while the driving current is supplied, thereby preventing the lifespan deterioration caused by carriers or excitons from accumulating at the interface, and improving the lifespan.

A light emitting device according to an embodiment of a present disclosure may comprise a first electrode and a second electrode facing each other and a hole transport layer, a light emitting layer, an efficiency-improving layer, and an electron transport layer sequentially stacked between the first electrode and the second electrode. The light emitting layer may comprise a first host of an anthracene derivative and a first blue light emitting dopant, and the efficiency-improving layer comprises a second host having bipolarity and a second blue light emitting dopant.

In a light emitting device according to an embodiment of a present disclosure, the second host of the efficiency-improving layer may comprise a single compound including both an electron-transporting functional group and a hole-transporting functional group.

In a light emitting device according to an embodiment of a present disclosure, the single compound may comprise either a triazine or a pyrimidine-based group and at least one of a carbazole-, a spirofluorene-, and a dibenzofuran-based group.

In a light emitting device according to an embodiment of a present disclosure, a thickness of the light emitting layer may be greater than a thickness of the efficiency-improving layer and may be smaller than a thickness of the electron transport layer.

In a light emitting device according to an embodiment of a present disclosure, a difference between a singlet excitation level and a triplet excitation level of the second host may be no less than 0.01 eV and may be no more than 0.3 eV. The triplet excitation level of the second host may be no less than 2.7 eV and may be no more than 3.4 eV.

In a light emitting device according to an embodiment of a present disclosure, the second host may have an energy band gap of 2.7 eV or more.

In a light emitting device according to an embodiment of a present disclosure, the first dopant and the second dopant may be the same as each other and have an emission peak at a wavelength of 400 nm to 490 nm.

In a light emitting device according to an embodiment of a present disclosure, the first dopant and the second dopant may have an emission peak at a wavelength of 400 nm to 490 nm. The second dopant may have a higher singlet excitation level and a higher triplet excitation level than those of the first dopant.

A light emitting device according to an embodiment of a present disclosure may further comprise an electron-blocking layer between the hole transport layer and the light emitting layer. The light emitting layer may have two surfaces that come into contact with the electron-blocking layer and the efficiency-improving layer, respectively.

In a light emitting device according to an embodiment of a present disclosure, the second host comprises a compound that may be selected from the LIH1 to LIH55 as stated above.

In a light emitting device according to an embodiment of a present disclosure, a first unit comprising the hole transport layer, the light emitting layer, the efficiency-improving layer, and the electron transport layer may be provided between the first electrode and the second electrode. The light emitting device may further comprise a second unit comprising at least one non-blue light emitting layer and a charge generating layer interposed between the first electrode and the second electrode.

A light emitting display device according to an embodiment of a present disclosure may comprise a substrate comprising a plurality of subpixels, a thin film transistor provided in each of the subpixels on the substrate and the light emitting device connected to the thin film transistor at least one of the subpixels.

It will be apparent to those skilled in the art that various modifications and variations can be made in the present disclosure without departing from the spirit or scope of the disclosure. Thus, it is intended that the present disclosure covers such modifications and variations thereto, provided they fall within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting device, comprising:
a first electrode and a second electrode facing each other; and
a first unit comprising a hole transport layer, a light emitting layer, an efficiency-improving layer, and an electron transport layer sequentially stacked between the first electrode and the second electrode,
wherein the light emitting layer comprises a first host comprising an anthracene derivative and a first blue light emitting dopant, and the efficiency-improving layer comprises a second host having bipolarity and a second blue light emitting dopant.

2. The light emitting device according to claim 1, wherein the second host of the efficiency-improving layer comprises a single compound including both an electron-transporting functional group and a hole-transporting functional group.

3. The light emitting device according to claim 1, wherein the second host comprises a compound including:
either a triazine- or a pyrimidine-based group; and
at least one of a carbazole-, a spirofluorene-, and a dibenzofuran-based group.

4. The light emitting device according to claim 1, wherein a thickness of the light emitting layer is greater than a thickness of the efficiency-improving layer and is smaller than a thickness of the electron transport layer.

5. The light emitting device according to claim 1, wherein a difference between a singlet excitation level and a triplet excitation level of the second host is no less than 0.01 eV and no more than 0.3 eV, and
the triplet excitation level of the second host is less than 2.7 eV and more than 3.4 eV.

6. The light emitting device according to claim 5, wherein the second host has an energy band gap of 2.7 eV or more.

7. The light emitting device according to claim 1, wherein the first blue dopant and the second blue dopant are the same as each other and have an emission peak at a wavelength of 400 nm to 490 nm.

8. The light emitting device according to claim 1, wherein the first blue emitting dopant and the second blue light emitting dopant independently have an emission peak at a wavelength of 400 nm to 490 nm, and
the second blue light emitting dopant has a higher singlet excitation level and a higher triplet excitation level than those of the first blue light emitting dopant.

9. The light emitting device according to claim 1, further comprising an electron-blocking layer between the hole transport layer and the light emitting layer, wherein the light emitting layer has a first surface in contact with the electron-blocking layer and a second surface opposite the first surface in contact with the efficiency-improving layer.

10. The light emitting device according to claim 1, wherein the second host is selected from the following LIH1 to LIH55:

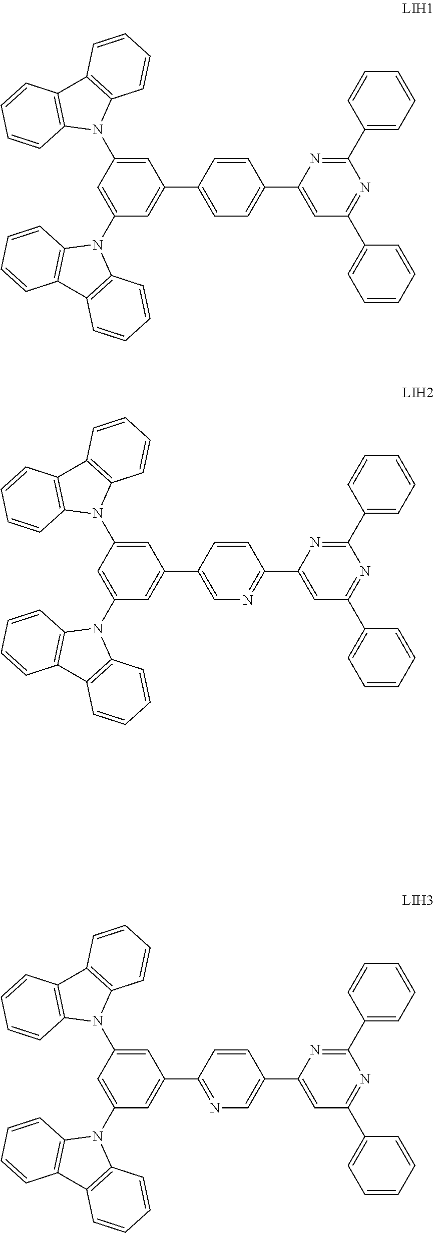 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)nc3)nc(-c3ccccc3)n2)cc1]

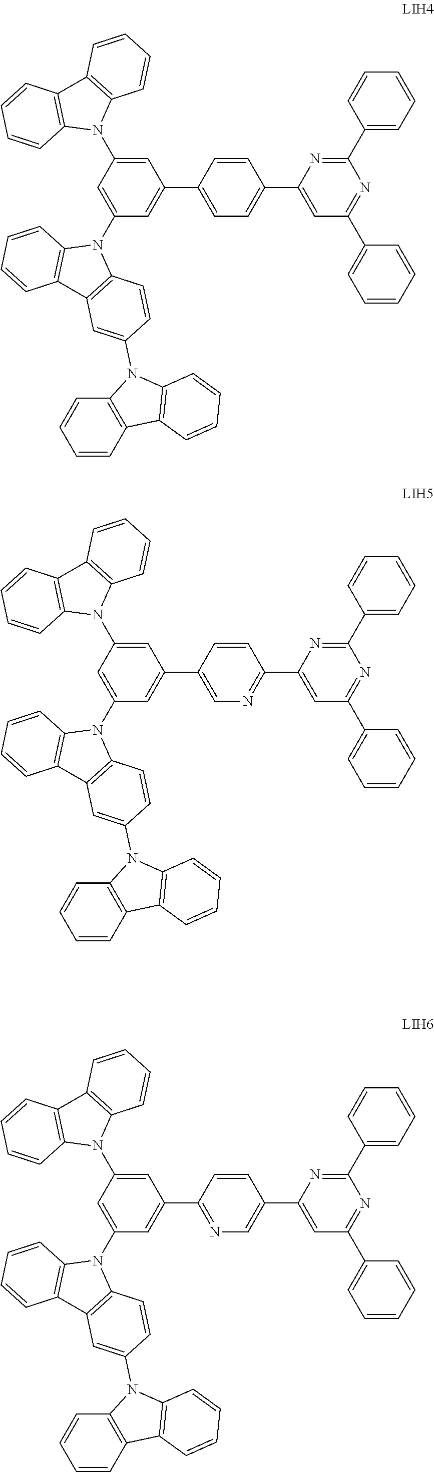 [SMILES: c1ccc(-c2cc(-c3ccc(-c4cc(-n5c6ccccc6c6ccccc65)cc(-n5c6ccccc6c6cc(-n7c8ccccc8c8ccccc87)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(-n7c8ccccc8c8ccccc87)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(-n7c8ccccc8c8ccccc87)ccc65)c4)nc3)nc(-c3ccccc3)n2)cc1]

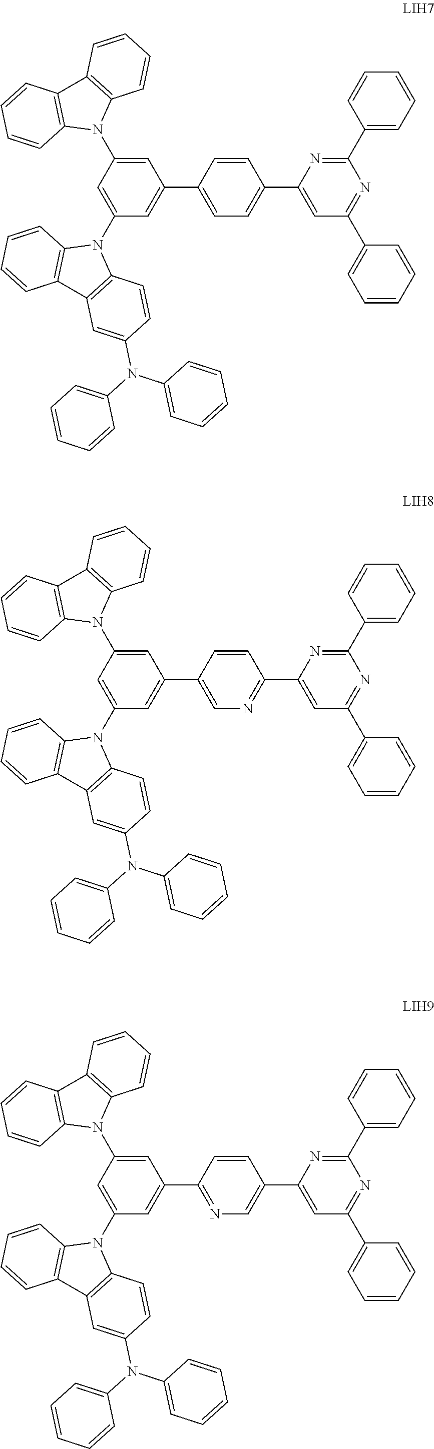 [SMILES: c1ccc(-c2cc(-c3ccc(-c4cc(-n5c6ccccc6c6ccccc65)cc(-n5c6ccccc6c6cc(N(c7ccccc7)c7ccccc7)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(N(c7ccccc7)c7ccccc7)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(N(c7ccccc7)c7ccccc7)ccc65)c4)nc3)nc(-c3ccccc3)n2)cc1]

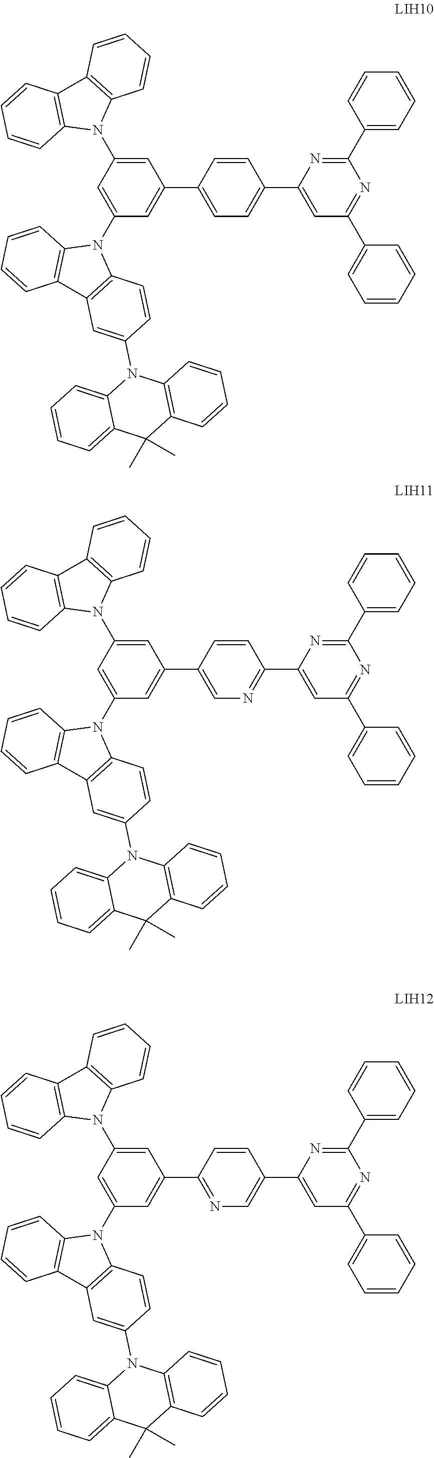 [SMILES: CC1(C)c2ccccc2N(c2ccc3c(c2)c2ccccc2n3-c2cc(-c3ccc(-c4cc(-c5ccccc5)nc(-c5ccccc5)n4)cc3)cc(-n3c4ccccc4c4ccccc43)c2)c2ccccc21 ; CC1(C)c2ccccc2N(c2ccc3c(c2)c2ccccc2n3-c2cc(-c3ccc(-c4cc(-c5ccccc5)nc(-c5ccccc5)n4)nc3)cc(-n3c4ccccc4c4ccccc43)c2)c2ccccc21 ; CC1(C)c2ccccc2N(c2ccc3c(c2)c2ccccc2n3-c2cc(-c3ccc(-c4cc(-c5ccccc5)nc(-c5ccccc5)n4)cn3)cc(-n3c4ccccc4c4ccccc43)c2)c2ccccc21]

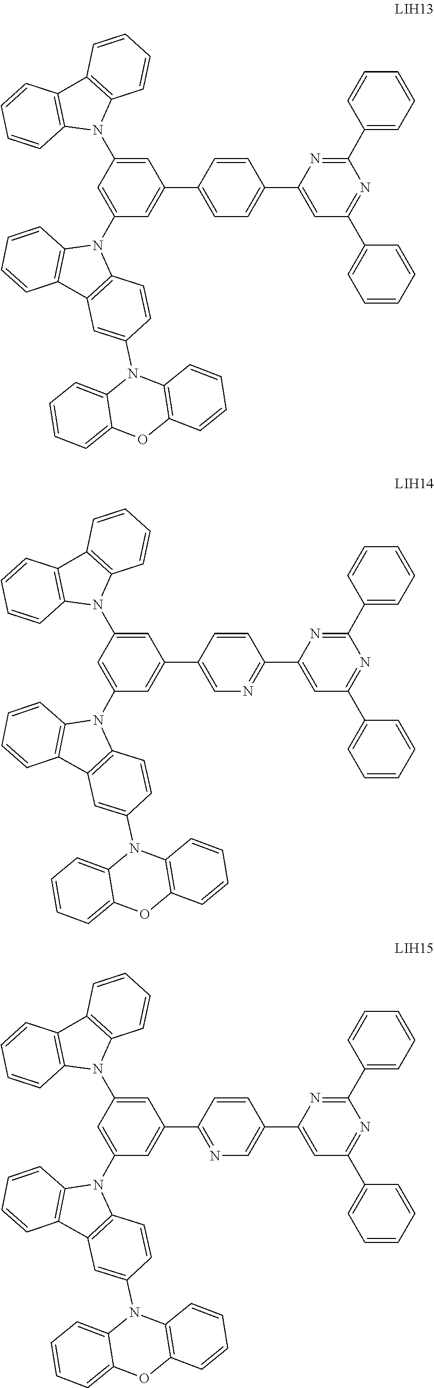 [SMILES: c1ccc(-c2cc(-c3ccc(-c4cc(-n5c6ccccc6c6ccccc65)cc(-n5c6ccccc6c6cc(N7c8ccccc8Oc8ccccc87)ccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6cc(N7c8ccccc8Oc8ccccc87)ccc65)c4)cn3)nc(-c3ccccc3)n2)cc1 ; c1ccc(-c2cc(-c3ccc(-c4cc(-n5c6ccccc6c6ccccc65)cc(-n5c6ccccc6c6cc(N7c8ccccc8Oc8ccccc87)ccc65)c4)nc3)nc(-c3ccccc3)n2)cc1]

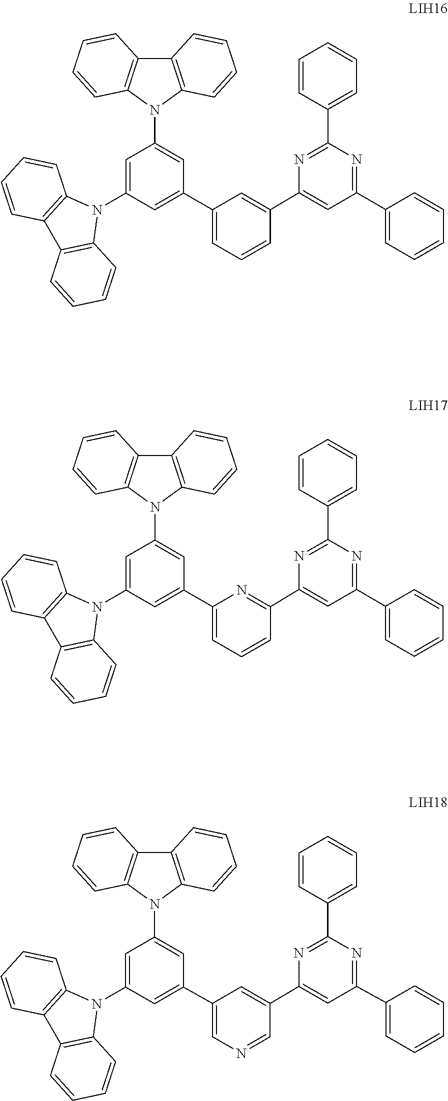 [SMILES: c1ccc(-c2cc(-c3cccc(-c4cc(-n5c6ccccc6c6ccccc65)cc(-n5c6ccccc6c6ccccc65)c4)c3)nc(-c3ccccc3)n2)cc1 ; c1ccc(-c2cc(-c3cccc(-c4cc(-n5c6ccccc6c6ccccc65)cc(-n5c6ccccc6c6ccccc65)c4)n3)nc(-c3ccccc3)n2)cc1 ; c1ccc(-c2cc(-c3cncc(-c4cc(-n5c6ccccc6c6ccccc65)cc(-n5c6ccccc6c6ccccc65)c4)c3)nc(-c3ccccc3)n2)cc1]

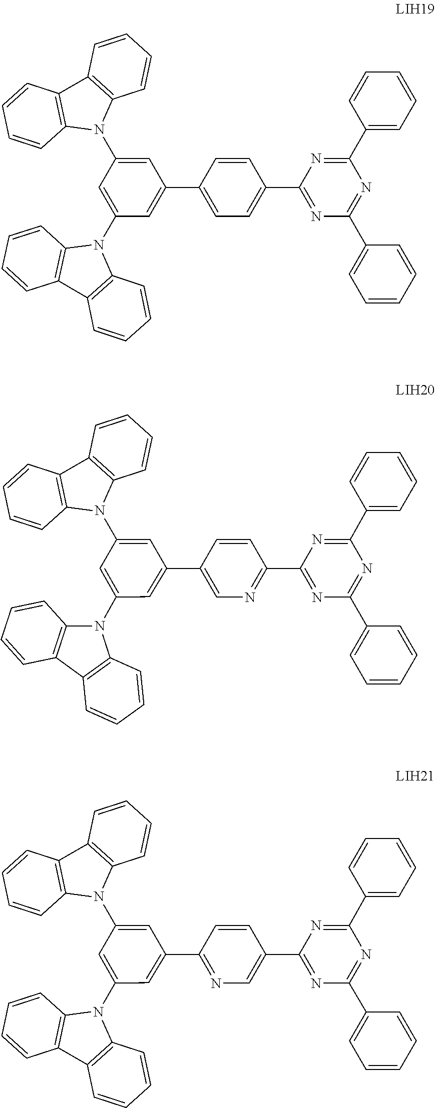 [SMILES: c1ccc(-c2nc(-c3ccccc3)nc(-c3ccc(-c4cc(-n5c6ccccc6c6ccccc65)cc(-n5c6ccccc6c6ccccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6ccccc65)c4)nc3)n2)cc1]

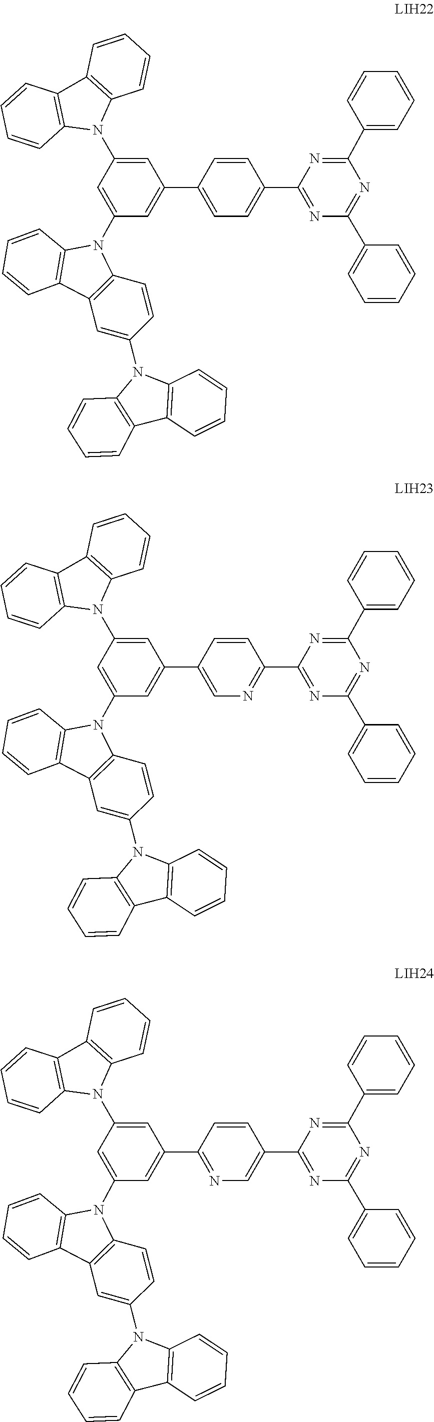 [SMILES: c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6cc(-n7c8ccccc8c8ccccc87)ccc65)c4)nc3)n2)cc1]

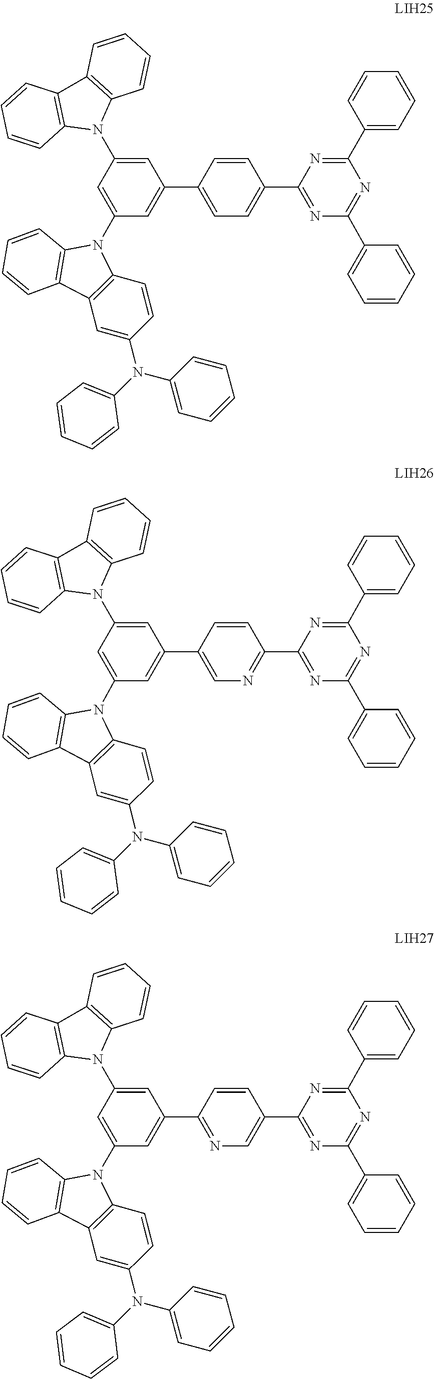 [SMILES: c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)cc3)n2)cc1 ; c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)cn3)n2)cc1 ; c1ccc(-c2nc(-c3ccccc3)nc(-c3ccc(-c4cc(-n5c6ccccc6c6ccccc65)cc(-n5c6ccccc6c6cc(N(c7ccccc7)c7ccccc7)ccc65)c4)nc3)n2)cc1]

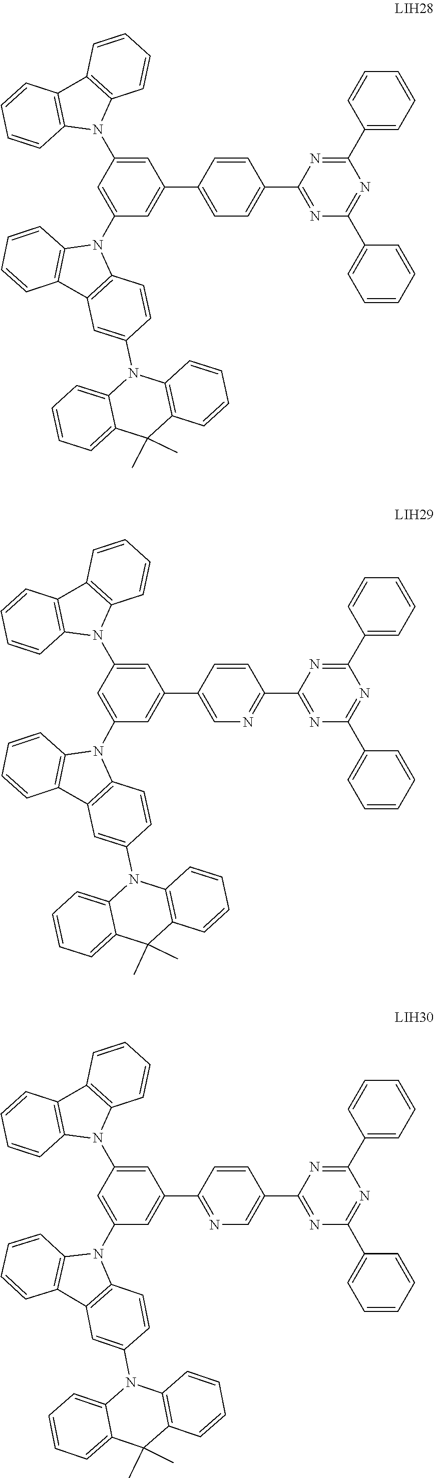 [SMILES: CC1(C)c2ccccc2N(c2ccc3c(c2)c2ccccc2n3-c2cc(-c3ccc(-c4nc(-c5ccccc5)nc(-c5ccccc5)n4)cc3)cc(-n3c4ccccc4c4ccccc43)c2)c2ccccc21 ; CC1(C)c2ccccc2N(c2ccc3c(c2)c2ccccc2n3-c2cc(-c3ccc(-c4nc(-c5ccccc5)nc(-c5ccccc5)n4)nc3)cc(-n3c4ccccc4c4ccccc43)c2)c2ccccc21 ; CC1(C)c2ccccc2N(c2ccc3c(c2)c2ccccc2n3-c2cc(-c3ccc(-c4nc(-c5ccccc5)nc(-c5ccccc5)n4)cn3)cc(-n3c4ccccc4c4ccccc43)c2)c2ccccc21]

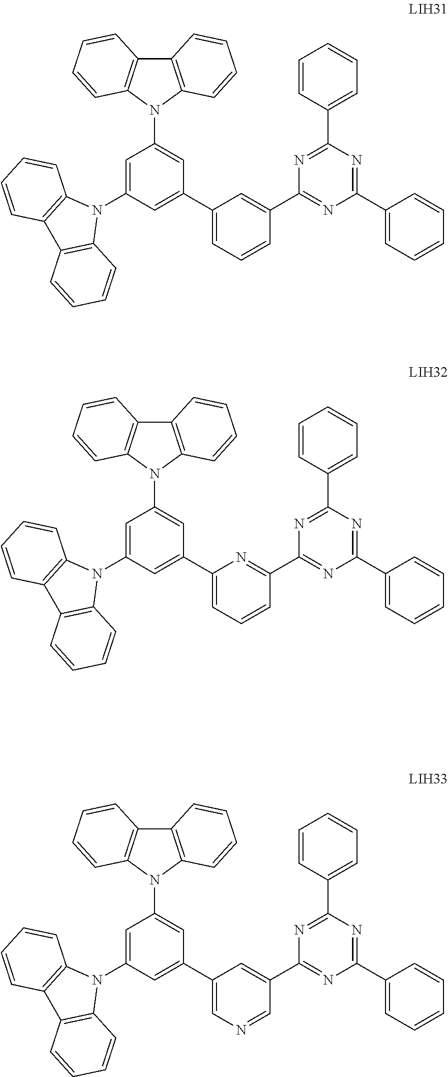 [SMILES: c1ccc(-c2nc(-c3ccccc3)nc(-c3cccc(-c4cc(-n5c6ccccc6c6ccccc65)cc(-n5c6ccccc6c6ccccc65)c4)c3)n2)cc1 ; c1ccc(-c2nc(-c3ccccc3)nc(-c3cccc(-c4cc(-n5c6ccccc6c6ccccc65)cc(-n5c6ccccc6c6ccccc65)c4)n3)n2)cc1 ; c1ccc(-c2nc(-c3ccccc3)nc(-c3cncc(-c4cc(-n5c6ccccc6c6ccccc65)cc(-n5c6ccccc6c6ccccc65)c4)c3)n2)cc1]

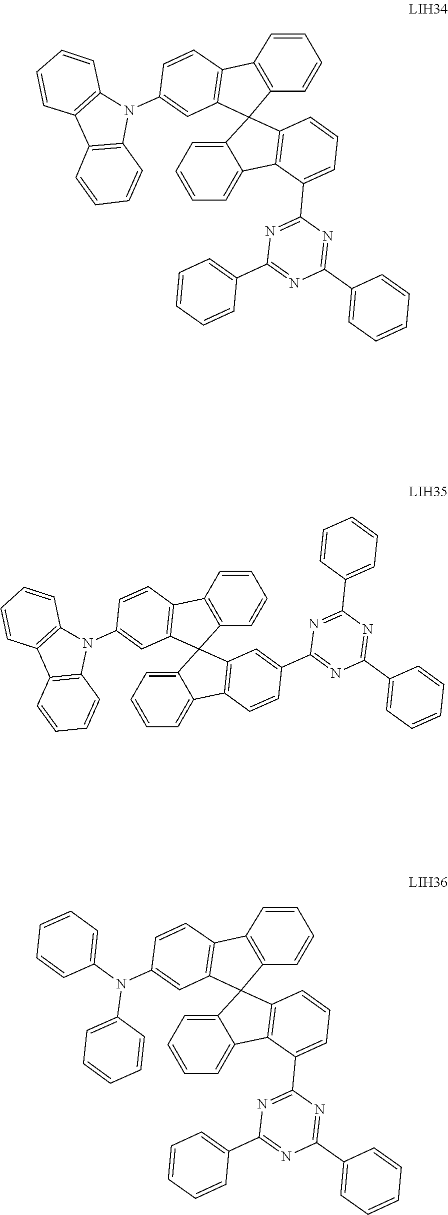 [SMILES: c1ccc(-c2nc(-c3ccccc3)nc(-c3cccc4c3-c3ccccc3C43c4ccccc4-c4ccc(-n5c6ccccc6c6ccccc65)cc43)n2)cc1 ; c1ccc(-c2nc(-c3ccccc3)nc(-c3ccc4c(c3)C3(c5ccccc5-4)c4ccccc4-c4ccc(-n5c6ccccc6c6ccccc65)cc43)n2)cc1 ; c1ccc(-c2nc(-c3ccccc3)nc(-c3cccc4c3-c3ccccc3C43c4ccccc4-c4ccc(N(c5ccccc5)c5ccccc5)cc43)n2)cc1]

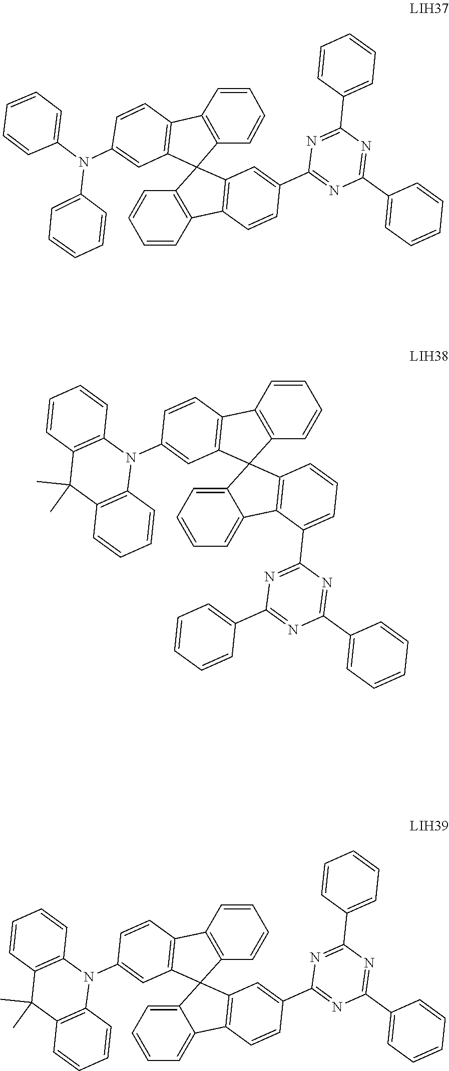 [SMILES: c1ccc(-c2nc(-c3ccccc3)nc(-c3ccc4c(c3)C3(c5ccccc5-4)c4ccccc4-c4ccc(N(c5ccccc5)c5ccccc5)cc43)n2)cc1 ; CC1(C)c2ccccc2N(c2ccc3c(c2)C2(c4ccccc4-3)c3ccccc3-c3c(-c4nc(-c5ccccc5)nc(-c5ccccc5)n4)cccc32)c2ccccc21 ; CC1(C)c2ccccc2N(c2ccc3c(c2)C2(c4ccccc4-c4ccc(-c5nc(-c6ccccc6)nc(-c6ccccc6)n5)cc42)c2ccccc2-3)c2ccccc21]

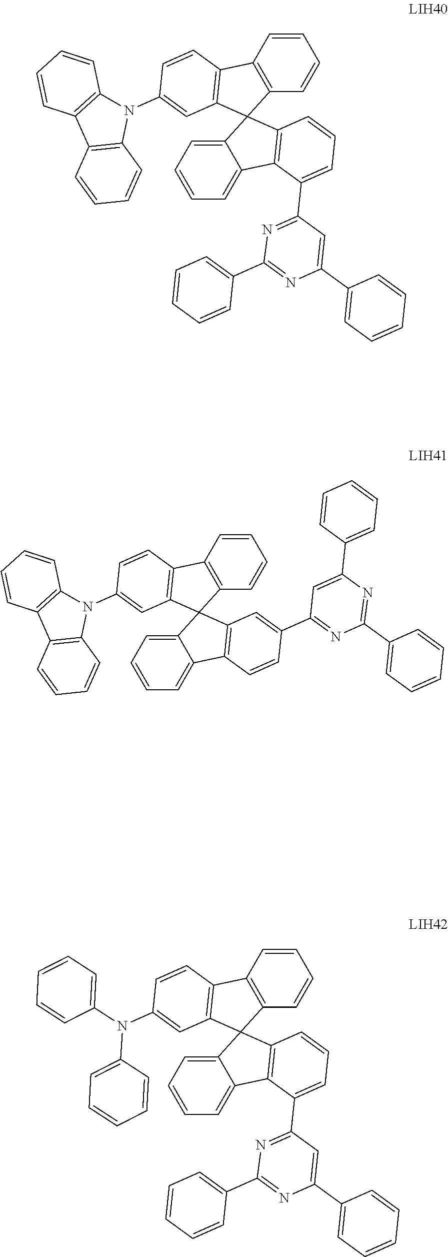 [SMILES: c1ccc(-c2cc(-c3cccc4c3-c3ccccc3C43c4ccccc4-c4ccc(-n5c6ccccc6c6ccccc65)cc43)nc(-c3ccccc3)n2)cc1 ; c1ccc(-c2cc(-c3ccc4c(c3)C3(c5ccccc5-4)c4ccccc4-c4ccc(-n5c6ccccc6c6ccccc65)cc43)nc(-c3ccccc3)n2)cc1 ; c1ccc(-c2cc(-c3cccc4c3-c3ccccc3C43c4ccccc4-c4ccc(N(c5ccccc5)c5ccccc5)cc43)nc(-c3ccccc3)n2)cc1]

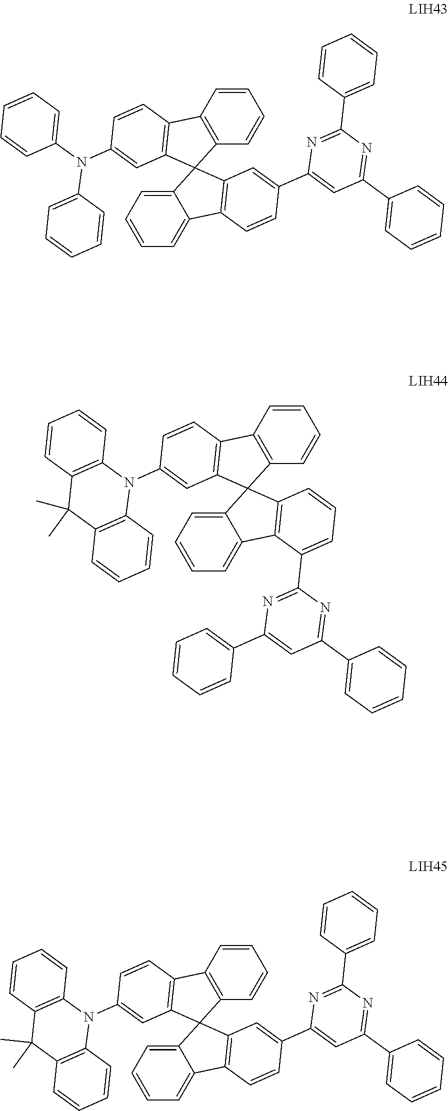 [SMILES: c1ccc(-c2cc(-c3ccc4c(c3)C3(c5ccccc5-4)c4ccccc4-c4ccc(N(c5ccccc5)c5ccccc5)cc43)nc(-c3ccccc3)n2)cc1 ; CC1(C)c2ccccc2N(c2ccc3c(c2)C2(c4ccccc4-3)c3ccccc3-c3c(-c4nc(-c5ccccc5)cc(-c5ccccc5)n4)cccc32)c2ccccc21 ; CC1(C)c2ccccc2N(c2ccc3c(c2)C2(c4ccccc4-c4ccc(-c5cc(-c6ccccc6)nc(-c6ccccc6)n5)cc42)c2ccccc2-3)c2ccccc21]

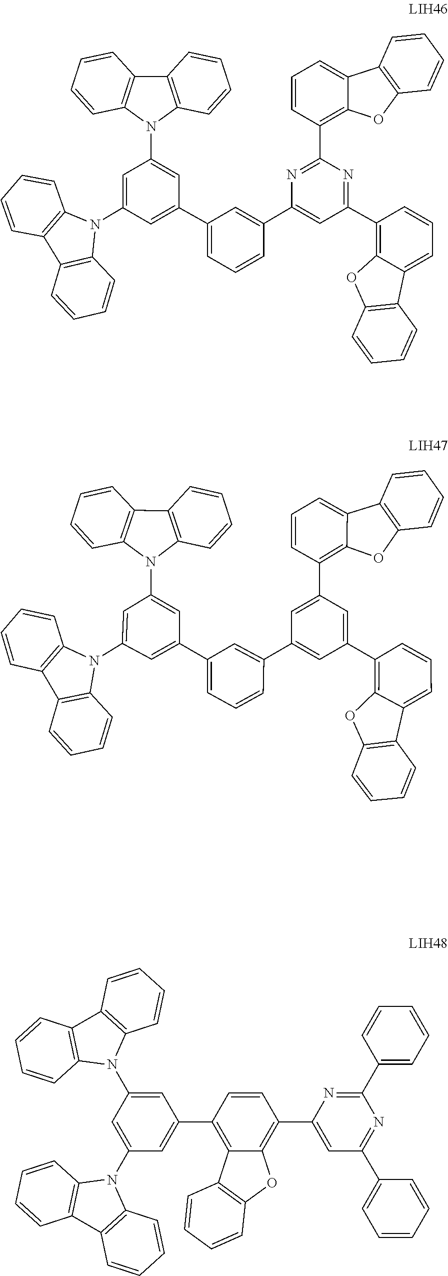 [SMILES: c1cc(-c2cc(-n3c4ccccc4c4ccccc43)cc(-n3c4ccccc4c4ccccc43)c2)cc(-c2cc(-c3cccc4c3oc3ccccc34)nc(-c3cccc4c3oc3ccccc34)n2)c1 ; c1cc(-c2cc(-c3cccc4c3oc3ccccc34)cc(-c3cccc4c3oc3ccccc34)c2)cc(-c2cc(-n3c4ccccc4c4ccccc43)cc(-n3c4ccccc4c4ccccc43)c2)c1 ; c1ccc(-c2cc(-c3ccc(-c4cc(-n5c6ccccc6c6ccccc65)cc(-n5c6ccccc6c6ccccc65)c4)c4c3oc3ccccc34)nc(-c3ccccc3)n2)cc1]

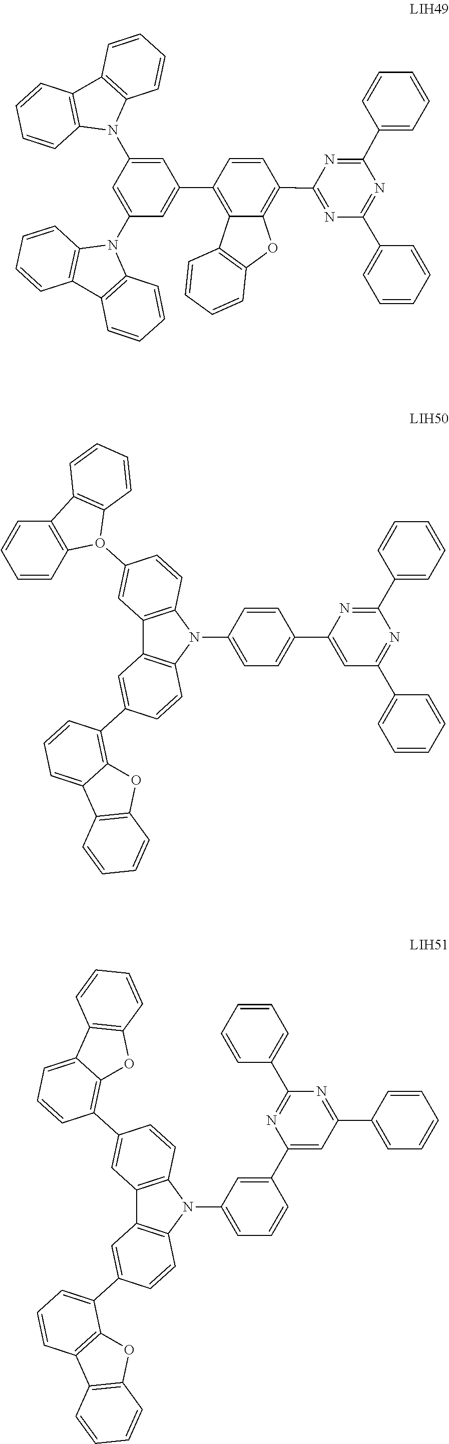

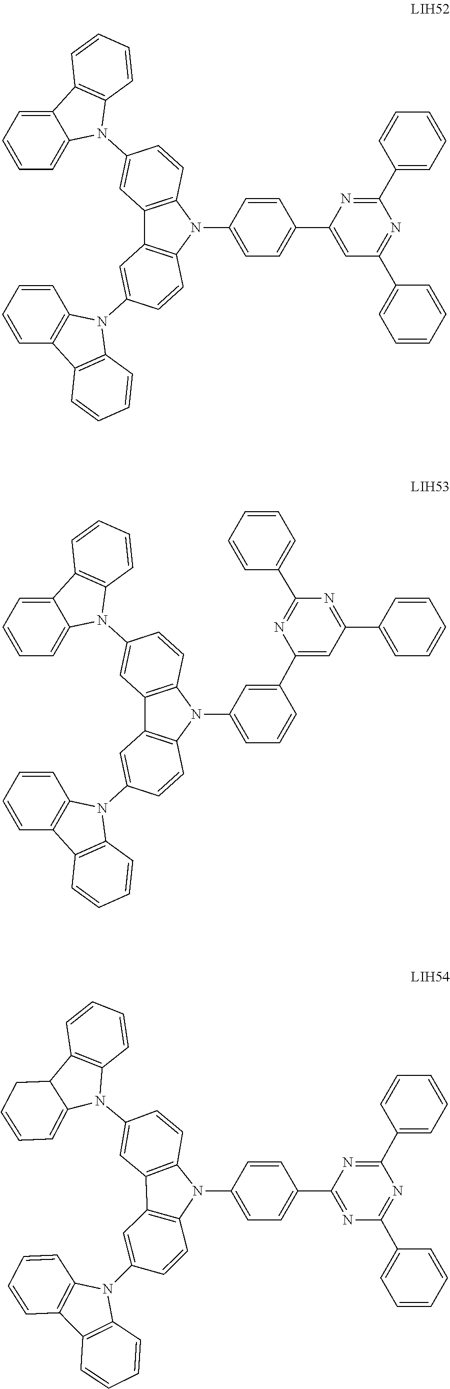 [SMILES: c1ccc(-c2cc(-c3ccc(-n4c5ccc(-n6c7ccccc7c7ccccc76)cc5c5cc(-n6c7ccccc7c7ccccc76)ccc54)cc3)nc(-c3ccccc3)n2)cc1 ; c1ccc(-c2cc(-c3cccc(-n4c5ccc(-n6c7ccccc7c7ccccc76)cc5c5cc(-n6c7ccccc7c7ccccc76)ccc54)c3)nc(-c3ccccc3)n2)cc1 ; C1=CCC2C(=C1)N(c1ccc3c(c1)c1cc(-n4c5ccccc5c5ccccc54)ccc1n3-c1ccc(-c3nc(-c4ccccc4)nc(-c4ccccc4)n3)cc1)c1ccccc12]

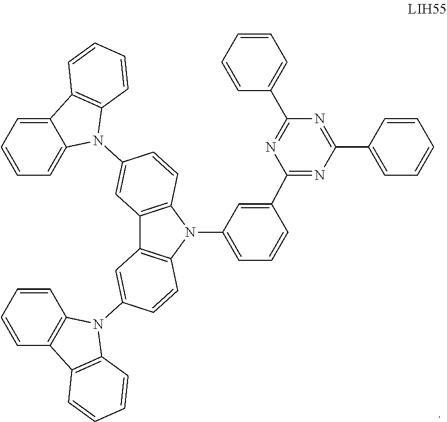 [SMILES: c1ccc(-c2nc(-c3ccccc3)nc(-c3cccc(-n4c5ccc(-n6c7ccccc7c7ccccc76)cc5c5cc(-n6c7ccccc7c7ccccc76)ccc54)c3)n2)cc1]

11. The light emitting device according to claim 1, further comprising a charge generating layer and a second unit comprising at least one non-blue light emitting layer between the first unit and the second electrode.

12. A light emitting display device, comprising:
a substrate comprising a plurality of subpixels;
a thin film transistor provided in each of the plurality of subpixels on the substrate; and
a light emitting device connected to the thin film transistor in at least one of the plurality of subpixels,
wherein the light emitting device comprising a first electrode and a second electrode facing each other and a unit comprising a hole transport layer, a light emitting layer, an efficiency-improving layer, and an electron transport layer sequentially stacked between the first electrode and the second electrode,
wherein the light emitting layer comprises a first host comprising an anthracene derivative and a first blue light emitting dopant, and the efficiency-improving layer comprises a second host having bipolarity and a second blue light emitting dopant.
